(19) United States
(12) Patent Application Publication
(10) Pub. No.: US 2013/0045440 A1
(43) Pub. Date: Feb. 21, 2013

(54) RESIST PATTERN FORMING METHOD, RESIST PATTERN, CROSSLINKING NEGATIVE CHEMICAL-AMPLIFICATION RESIST COMPOSITION FOR ORGANIC SOLVENT DEVELOPMENT, NANOIMPRINT MOLD, AND PHOTOMASK

(71) Applicants: Toru TSUCHIHASHI, Shizuoka (JP); Michihiro SHIBATA, Kanagawa (JP)

(72) Inventors: Toru TSUCHIHASHI, Shizuoka (JP); Michihiro SHIBATA, Kanagawa (JP)

(73) Assignee: FUJIFILM CORPORATION, Tokyo (JP)

(21) Appl. No.: 13/586,245

(22) Filed: Aug. 15, 2012

(30) Foreign Application Priority Data
Aug. 17, 2011 (JP) 2011-178533

(51) Int. Cl. G03F 7/027; B29C 59/02; B32B 3/10; G03F 7/20; G03F 1/00

(52) U.S. Cl. 430/5; 430/325; 430/296; 430/286.1; 428/195.1; 425/385

(57) ABSTRACT

A resist pattern forming method contains, in order: (1) a step of forming a resist film by using a negative chemical-amplification resist composition containing: (A) polymer compound having a repeating unit represented by the specific formula, (B) a phenolic compound being capable of crosslinking the polymer compound (A) by the action of an acid and having two or more benzene rings and four or more alkoxymethyl groups, and (C) a compound capable of generating an acid upon irradiation with an actinic ray or radiation, (2) a step of exposing the film, and (4) a step of, after exposure, developing the film by using a developer containing an ester-based solvent having a carbon number of 7 or 8.

### BACKGROUND OF THE INVENTION

1. Field of the Invention

The present invention relates to a resist pattern forming method using a negative chemical-amplification resist composition, which is suitably used for the ultramicrolithography process such as production of VLSI or high-capacity microchip or in other photofabrication processes. More specifically, the present invention relates to a resist pattern forming method, a resist pattern, a crosslinking negative chemical-amplification resist composition for organic solvent development, a nanoimprint mold, and a photomask, each suitably usable in the microfabrication of a semiconductor, where an electron beam, an X-ray or EUV light (wavelength: near 13 nm) is used.

2. Description of the Related Art

In the process of producing a semiconductor device such as IC and LSI, microfabrication by lithography using a photoresist composition has been conventionally performed. Recently, with increase in the integration degree of an integrated circuit, the exposure wavelength also tends to become shorter, for example, from g line to i line or further to KrF excimer laser light. Furthermore, development of lithography using an electron beam, an X-ray or EUV light is also proceeding.

Such electron beam, X-ray or EUV light lithography is positioned as the next-generation or next-next-generation pattern formation technology, and a technique for forming a high-sensitivity, high-resolution and low-defect pattern is being demanded.

The method generally employed for forming a resist pattern is a method where a resist composition is patternwise exposed by irradiation with an electron beam or an actinic ray and subsequently developed using an aqueous alkali solution. However, in the formation of an ultrafine pattern, more improvement is demanded on the resolution.

In the case of development using an aqueous alkali solution, thanks to a great difference in solubility of the resist film between the exposed area and the unexposed area, a very large dissolution contrast can be obtained. However, in the case of forming a fine pattern, the difference in solubility is locally increased due to an excessively large dissolution contrast, giving rise to, for example, looseness of the pattern surface or partial breaking off of the pattern, and the quality of the pattern is impaired. Also, the aqueous alkali solution has a high surface tension and therefore, is less likely to penetrate into a fine space part, and this causes another problem that a defect such as scum or bridge is readily generated in the space part.

In order to solve these problems, for example, a negative pattern forming method where development using an organic solvent is performed has been proposed (see, for example, JP-A-7-261392 (the term “JP-A” as used herein means an “unexamined published Japanese patent application”) and JP-A-2010-256858). However, it has been so far not successful to satisfy high sensitivity, high resolution and scum reduction in the unexposed area all at the same time particularly in the formation of an ultrafine pattern (for example, a 1:1 line-and-space pattern with a line width of 40 nm or less).

### SUMMARY OF THE INVENTION

An object of the present invention is to provide a resist pattern forming method, a resist pattern, a crosslinking negative chemical-amplification resist composition for organic solvent development, a nanoimprint mold, and a photomask, ensuring that a pattern satisfying high sensitivity, high resolution (for example, high resolving power and small line edge roughness (LER)) and scum reduction in the unexposed area all at the same time can be formed even in the formation of an ultrafine pattern (for example, a 1:1 line-and-space pattern with a line width of 40 nm or less).

As a result of intensive studies, the present inventors have found that when a crosslinking negative resist containing a polymer compound having a specific structure and a crosslinking agent is patternwise exposed and then developed using a developer containing an organic solvent having a specific structure, the above-described object can be achieved.

That is, the present invention is as follows.

[1] A resist pattern forming method comprising, in order:

(1) a step of forming a resist film by using a negative chemical-amplification resist composition containing:
(A) polymer compound having a repeating unit represented by the following formula (I),
(B) a phenolic compound being capable of crosslinking the polymer compound (A) by the action of an acid and having two or more benzene rings and four or more alkoxymethyl groups, and
(C) a compound capable of generating an acid upon irradiation with an actinic ray or radiation,

(2) a step of exposing the film, and

(4) a step of, after exposure, developing the film by using a developer containing an ester-based solvent having a carbon number of 7 or 8:

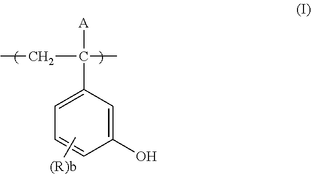

wherein, in formula (I), A represents a hydrogen atom, an alkyl group, a cycloalkyl group, a halogen atom or a cyano group;

R represents a halogen atom, an alkyl group, a cycloalkyl group, an aryl group, an alkenyl group, an aralkyl group, an alkoxy group, an alkylcarbonyloxy group or an alkylsulfonyloxy group, and when a plurality of Rs are present, each R may be the same as or different from every other R and they may combine to form a ring; and

b represents an integer of 0 to 2.

[2] The resist pattern forming method as described in [1] above,

wherein the ester-based solvent having a carbon number of 7 or 8 contained in the developer is an ester-based solvent represented by the following formula (II):

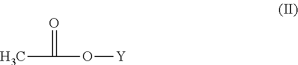

wherein, in formula (II), Y represents an alkyl group or a cycloalkyl group, having a carbon number of 5 or 6.

[3] The resist pattern forming method as described in [2] above,

wherein the ester-based solvent having a carbon number of 7 or 8 contained in the developer is one or more kinds of solvents selected from the group consisting of n-pentyl acetate, 3-methylbutyl acetate, 2-methylbutyl acetate, n-hexyl acetate, cyclohexyl acetate, 2-ethylbutyl acetate and 3-methylpentyl acetate.

[4] The resist pattern forming method as described in any one of [1] to [3] above, further comprising:

(5) a step of performing a rinsing treatment by using an organic solvent containing one or more kinds of solvents selected from the group consisting of a monohydric alcohol-based solvent and a hydrocarbon-based solvent, after the development step (4).

[5] The resist pattern forming method as described in any one of [1] to [4] above,

wherein in the development step (4), the development is performed by continuously supplying a substantially fresh developer.

[6] The resist pattern forming method as described in any one of [1] to [5] above, further comprising:

(3) a baking step between the exposure step (2) and the development step (4).

[7] The resist pattern forming method as described in any one of [1] to [6] above,

wherein the exposing in the exposure step (2) is performed by an electron beam or EUV light.

[8] The resist pattern forming method as described in any one of [1] to [7] above,

wherein the negative chemical-amplification resist composition contains, as (C) the compound capable of generating an acid upon irradiation with an actinic ray or radiation, (C′) an ionic compound capable of generating an acid upon irradiation with an actinic ray or radiation in an amount of 9 mass % or more based on the entire solid content of the negative chemical-amplification resist composition.

[9] The resist pattern forming method as described in any one of [1] to [8] above,

wherein the compound (C) is a compound capable of generating at least any acid of a sulfonic acid, a bis(alkylsulfonyl)imide and a tris(alkylsulfonyl)methide upon irradiation with an actinic ray or radiation.

[10] A resist pattern formed by the resist pattern forming method as described in any one of [1] to [9] above.
[11] A crosslinking negative chemical-amplification resist composition for organic solvent development, which is used for the resist pattern forming method as described in any one of [1] to [9] above.
[12] A nanoimprint mold produced by the resist pattern forming method as described in any one of [1] to [9] above.
[13] A photomask produced by the resist pattern forming method as described in any one of [1] to [9] above.

According to the present invention, a resist pattern forming method, a resist pattern, a crosslinking negative chemical-amplification resist composition for organic solvent development, a nanoimprint mold, and a photomask, ensuring that a pattern satisfying high sensitivity, high resolution (for example, high resolving power and small line edge roughness (LER)) and scum reduction in the unexposed area all at the same time can be formed even in the formation of an ultrafine pattern (for example, a 1:1 line-and-space pattern with a line width of 40 nm or less), can be provided.

### DETAILED DESCRIPTION OF THE INVENTION

The resist pattern forming method, the crosslinking negative chemical-amplification resist composition for organic solvent development, the nanoimprint mold, and the photomask of the present invention are described in detail below.

Incidentally, in the description of the present invention, when a group (atomic group) is denoted without specifying whether substituted or unsubstituted, the group encompasses both a group having no substituent and a group having a substituent. For example, “an alkyl group” encompasses not only an alkyl group having no substituent (unsubstituted alkyl group) but also an alkyl group having a substituent (substituted alkyl group).

In the present invention, the term “actinic ray” or “radiation” means, for example, a bright line spectrum of mercury lamp, a far ultraviolet ray typified by excimer laser, an extreme-ultraviolet ray (EUV light), an X-ray or an electron beam. Also, in the present invention, the “light” means an actinic ray or radiation.

In the description of the present invention, unless otherwise indicated, the “exposure (exposing)” encompasses not only exposure to a mercury lamp, a far ultraviolet ray typified by excimer laser, an X-ray, EUV light or the like but also lithography with a particle beam such as electron beam and ion beam.

### [Resist Pattern Forming Method and Resist Pattern]

The mode for using the negative chemical-amplification resist composition of the present invention is described below.

The resist pattern forming method of the present invention comprises, in order, (1) a step of forming a resist film by using the later-described negative chemical-amplification resist composition capable of undergoing negative conversion by a crosslinking reaction, (2) a step of exposing the film, and (4) a step of, after exposure, developing the film by using a developer containing an ester-based solvent having a carbon number of 7 or 8.

The term “negative conversion” as used herein means that the molecular weight of the resin is increased by a crosslinking reaction to insolubilize the resin in a solvent (developer).

The resist pattern of the present invention is formed by the above-described pattern forming method of the present invention.

The present invention also relates to a crosslinking negative chemical-amplification resist composition for organic solvent developer, which is used for the resist pattern forming method of the present invention as described later.

### (1) Film Formation

For obtaining a negative chemical-amplification resist composition film, respective components described later are dissolved in a solvent, and the solution is filtered through a filter, if desired, and then coated on a support (substrate). The filter is preferably a polytetrafluoroethylene-, polyethylene- or nylon-made filter having a pore size of 0.1 μm or less, more preferably 0.05 μm or less, still more preferably 0.03 μm or less. The coating film is prebaked at 60 to 150° C. for 1 to 20 minutes, preferably at 80 to 140° C. for 1 to 10 minutes, to form a thin film.

The composition is coated on such a substrate as used in the production of an integrated circuit device (for example, a silicon- or silicon dioxide-coated substrate) by an appropriate coating method such as spinner and then dried to form a photosensitive film.

If desired, a commercially available inorganic or organic antireflection film may be used. Furthermore, an antireflection film may be also used by coating it as an underlying layer of the resist.

### (2) Exposure

The film formed is irradiated with an actinic ray or radiation through a predetermined mask. Incidentally, in the case of irradiation with an electron beam, lithography without the intervention of a mask (direct lithography) is generally performed.

The actinic ray or radiation is not particularly limited, but examples thereof include KrF excimer laser, ArF excimer laser, EUV light and electron beam, with EUV light and electron beam being preferred. That is, the exposing in (2) the step of exposing the film is preferably performed using an electron beam or EUV light.

### (3) Baking

The exposed film is preferably baked (heated) before performing development.

The heating temperature is preferably from 80 to 150° C., more preferably from 90 to 150° C., still more preferably from 100 to 140° C.

The heating time is preferably from 30 to 600 seconds, more preferably from 30 to 300 seconds, still more preferably from 60 to 300 seconds.

The heating may be performed by means of a device usually attached to an exposure/developing machine or may be also performed using a hot plate or the like.

The reaction of the exposed area is accelerated by the baking and in turn, the sensitivity or pattern profile is improved.

### (4) Development

In the present invention, development is performed using a developer containing an ester-based organic solvent having a carbon number of 7 or 8. The ester-based solvent having a carbon number of 7 or 8 is preferably an ester-based solvent represented by the following formula (II):

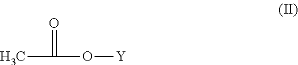

In formula (II), Y represents an alkyl group or a cycloalkyl group, having a carbon number of 5 or 6.

The ester-based solvent having a carbon number of 7 or 8 contained in the developer is more preferably one or more kinds of solvents selected from the group consisting of n-pentyl acetate, 3-methylbutyl acetate, 2-methylbutyl acetate, n-hexyl acetate, cyclohexyl acetate, 2-ethylbutyl acetate and 3-methylpentyl acetate.

The ester-based solvent having a carbon number of 7 or 8 is particularly preferably 3-methylbutyl acetate, n-hexyl acetate, or cyclohexyl acetate.

The development is performed using a developer containing the above-described organic solvent, whereby high sensitivity, high resolution (for example, high resolving power and small line edge roughness (LER)) and scum reduction in the unexposed area can be satisfied all at the same time in the pattern formation (particularly, in the formation of an ultrafine pattern (for example, a 1:1 line-and-space pattern with a line width of 40 nm or less)) using the later-described resist composition.

If the carbon number of the ester-based solvent contained in the developer is 6 or less, the resist pattern is swelled with the developer, giving rise to low resolving power and large LER, as a result, the resolution is poor.

If the carbon number of the ester-based solvent contained in the developer is 9 or more, the unexposed area of the resist film is hardly dissolved in the developer and not only the resolving power is reduced but also scum in the unexposed area is readily generated.

The ester-based solvent having a carbon number of 7 or 8 contained in the developer is preferably an ester-based solvent having a carbon number of 8. Also, Y in formula (II) is preferably an alkyl group or a cycloalkyl group, having a carbon number of 6. Thanks to this configuration, the above-described swelling of the resist pattern is more suppressed, and the resolution is more enhanced. Also, the solubility of the resist film in the unexposed area is sufficiently maintained, so that scum generation can be more suppressed.

The developer contains an organic solvent and may contain a plurality of kinds of organic solvents or may contain water, but as described above, the developer contains, as the organic solvent, an ester-based solvent having a carbon number of 7 or 8. Incidentally, the developer may contain a plurality of kinds of ester-based solvents having a carbon number of 7 or 8.

The concentration of the organic solvent (in the case of mixing a plurality of kinds of organic solvents, the total concentration) in the developer is preferably 50 mass % or more, more preferably 70 mass % or more, still more preferably 90 mass % or more. Above all, the developer is preferably composed of substantially only an organic solvent. The expression “composed of substantially only an organic solvent” encompasses a case containing a slight amount of a surfactant, an antioxidant, a stabilizer, a defoaming agent or the like, and specifically, the concentration of the organic solvent in the developer is preferably from 99.0 to 100 mass %, more preferably from 99.5 to 100 mass %. (In this specification, mass ratio is equal to weight ratio.)

The concentration of the ester-based solvent having a carbon number of 7 or 8 (in the case of mixing a plurality of kinds of ester-based solvents, the total concentration) in the developer is preferably 50 mass % or more, more preferably 70 mass % or more, still more preferably 90 mass % or more. Above all, the developer is preferably composed of substantially only an ester-based solvent having a carbon number of 7 or 8. The expression “composed of substantially only an ester-based solvent having a carbon number of 7 or 8” encompasses a case containing a slight amount of a surfactant, an antioxidant, a stabilizer, a defoaming agent or the like, and specifically, the concentration of the ester-based solvent having a carbon number of 7 or 8 in the developer is preferably from 99.0 to 100 mass %, more preferably from 99.5 to 100 mass %.

As the organic solvent other than the ester-based solvent having a carbon number of 7 or 8, which may be contained in the developer, one or more kinds of solvents selected from the group consisting of an ester-based solvent having a carbon number of 1 to 6 or 9 or more, a ketone-based solvent, an alcohol-based solvent, an amide-based solvent, an ether-based solvent and a hydrocarbon-based solvent, may be used.

Examples of the ester-based solvent having a carbon number of 1 to 6 or 9 or more include an alkyl carboxylate-based solvent such as methyl acetate, ethyl acetate, n-butyl acetate, isopropyl acetate, methyl formate, ethyl formate, butyl formate, propyl formate, ethyl lactate and propyl lactate, and an alkylene glycol monoalkyl ether carboxylate-based solvent such as propylene glycol monomethyl ether acetate (PGMEA; another name: 1-methoxy-2-acetoxypropane), ethylene glycol monoethyl ether acetate and diethylene glycol monobutyl ether acetate.

Examples of the ketone-based solvent include 1-octanone, 2-octanone, 1-nonanone, 2-nonanone, acetone, 4-heptanone, 1-hexanone, 2-hexanone, diisobutyl ketone, cyclopentanone, cyclohexanone, cycloheptanone, methylcyclohexanone, phenylacetone, methyl ethyl ketone, methyl amyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, hexyl alcohol (e.g., n-hexyl alcohol), heptyl alcohol (e.g., n-heptyl alcohol), octyl alcohol (e.g., n-octyl alcohol) and decanol (e.g., n-decanol); a glycol-based solvent such as ethylene glycol, diethylene glycol, triethylene glycol, 1,2-propylene glycol, 1,3-propylene glycol, 1,2-butylene glycol, 1,3-butylene glycol and 1,4-butylene glycol; an alkylene glycol monoalkyl ether-based solvent such as ethylene glycol monomethyl ether, propylene glycol monomethyl ether (PGME; another name: 1-methoxy-2-propanol), ethylene glycol monoethyl ether, propylene glycol monoethyl ether, diethylene glycol monomethyl ether and triethylene glycol monoethyl ether; a glycol ether-based solvent such as methoxymethyl butanol and propylene glycol dimethyl ether; and a phenol-based solvent such as phenol and cresol.

Examples of the amide-based solvent which can be used include N-methyl-2-pyrrolidone, N,N-dimethylacetamide, N,N-dimethylformamide, hexamethylphosphoric triamide, and 1,3-dimethyl-2-imidazolidinone.

Examples of the ether-based solvent include, in addition to the alkylene glycol monoalkyl ether-based solvents and glycol ether-based solvents above, dioxane, tetrahydropyran, and tetrahydropyran.

Examples of the hydrocarbon-based solvent include an aromatic hydrocarbon-based solvent such as toluene and xylene, and an aliphatic hydrocarbon-based solvent such as pentane, hexane, octane, decane, undecane and dodecane.

The percentage of water content in the developer is preferably 10 mass % or less, more preferably 5 mass % or less, still more preferably 3 mass % or less, and it is most preferred to contain substantially no water (specifically, the percentage of water content in the developer is preferably 1 mass % or less, more preferably 0.5 mass % or less, ideally 0 mass %, that is, the developer does not contain water). By virtue of setting the percentage of water content to 10 mass % or less, good development characteristics can be obtained.

### Surfactant:

In the developer containing an organic solvent, an appropriate amount of a surfactant can be added, if desired.

As for the surfactant, the same as the later-described surfactant used in the resist composition may be used.

The amount of the surfactant used is usually from 0.001 to 5 mass %, preferably from 0.005 to 2 mass %, more preferably from 0.01 to 0.5 mass %, based on the entire amount of the developer.

### Developing Method:

As regards the developing method, for example, a method of dipping the substrate in a bath filled with the developer for a fixed time (dipping method), a method of raising the developer on the substrate surface by the effect of a surface tension and keeping it still for a fixed time, thereby performing the development (puddle method), a method of spraying the developer on the substrate surface (spraying method), and a method of continuously ejecting the developer on the substrate spinning at a constant speed while scanning the developer ejecting nozzle at a constant rate (dynamic dispense method) may be applied.

Also, after the step of performing development, a step of stopping the development while replacing the developer by another solvent may be practiced.

In particular, the developing method is preferably a method of performing the development by continuously supplying a substantially fresh developer, specifically, a method of continuously spraying a substantially fresh developer on the substrate surface (spraying method) or a method of continuously ejecting a substantially fresh developer on the substrate spinning at a constant speed while scanning the developer ejecting nozzle at a constant rate (dynamic dispense method). The development is performed by continuously supplying a substantially fresh developer, whereby development of the exposed area proceeds swiftly and the resolution performance is enhanced. Furthermore, when the development is performed by keeping the continuous supply of a fresh developer, a scum-type development defect that is generated at the switching stage from development to rinsing can be more reduced.

The developing time is preferably a time long enough to sufficiently dissolve the resin, crosslinking agent and the like in the unexposed area and, usually, the developing time is preferably from 10 to 300 seconds, more preferably from 20 to 120 seconds.

The temperature of the developer is preferably from 0 to 50° C., more preferably from 15 to 35° C.

The amount of the developer can be appropriately adjusted according to the developing method.

### (5) Rinsing

The pattern forming method of the present invention may contain (5) a step of rinsing the film by using a rinsing solution containing an organic solvent after the development step (4).

### Rinsing Solution:

The organic solvent used for the rinsing solution is an organic solvent having a vapor pressure at 20° C. of preferably from 0.05 to 5 kPa, more preferably from 0.1 to 5 kPa, and most preferably from 0.12 to 3 kPa. By setting the vapor pressure of the organic solvent used for the rinsing solution to from 0.05 to 5 kPa, the temperature uniformity in the wafer plane is enhanced and swelling ascribable to permeation of the rinsing solution is suppressed, as a result, the dimensional uniformity in the wafer plane is improved.

As the rinsing solution, various organic solvents may be used, but in the case of using the above-described developer and a resist composition containing (A) a polymer compound containing a repeating unit represented by formula (I) and (B) a phenolic compound having two or more benzene rings and four or more alkoxymethyl groups, a rinsing solution containing at least one kind of a solvent selected from a hydrocarbon-based solvent and an alcohol-based solvent or containing water is preferably used.

The rinsing solution is more preferably a rinsing solution containing at least one or more kinds of organic solvents selected from a monohydric alcohol-based solvent and a hydrocarbon-based solvent, still more preferably a hydrocarbon-based solvent having a carbon number of 10 to 12.

The monohydric alcohol-based solvent used in the rinsing step after development includes a linear, branched or cyclic monohydric alcohol, and specific examples thereof include 1-butanol, 2-butanol, 3-methyl-1-butanol, tert-butyl alcohol, isopropyl alcohol, pentanol, and hexanol.

The hydrocarbon-based solvent includes an aromatic hydrocarbon-based solvent such as toluene and xylene, and an aliphatic hydrocarbon-based solvent such as octane, decane, undecane and dodecane.

As for each of these components, a plurality of kinds may be mixed, or the component may be used by mixing it with an organic solvent other than those described above.

The above-described organic solvent may be mixed with water, but the percentage of water content in the rinsing solution is usually 30 mass % or less, preferably 10 mass % or less, more preferably 5 mass % or less, still more preferably 3 mass % or less. The rinsing solution most preferably contains no water. By setting the percentage of water content to 30 mass % or less, good development characteristics can be obtained.

The rinsing solution may be also used after adding thereto an appropriate amount of a surfactant.

As the surfactant, the same as the later-described surfactant used in the resist composition may be used, and the amount used thereof is usually from 0.001 to 5 mass %, preferably from 0.005 to 2 mass %, more preferably from 0.01 to 0.5 mass %, based on the entire amount of the rinsing solution.

### Rinsing Method:

In the rinsing step, the developed wafer is subjected to a washing treatment using the above-described rinsing solution containing an organic solvent.

The method for washing treatment is not particularly limited but, for example, a method of continuously ejecting the rinsing solution on the substrate spinning at a constant speed (spin coating method), a method of dipping the substrate in a bath filled with the rinsing solution for a fixed time (dipping method), and a method of spraying the rinsing solution on the substrate surface (spraying method) may be applied. Above all, it is preferred that the washing treatment is performed by the spin coating method and after the washing, the rinsing solution is removed from the substrate surface by rotating the substrate at a rotation speed of 2,000 to 4,000 rpm. The rotation time of the substrate may be set according to the rotation speed in the range achieving removal of the rinsing solution from the substrate surface but is usually from 10 seconds to 3 minutes. Here, the rinsing is preferably performed under room-temperature conditions.

The rinsing time is preferably long enough to allow for no remaining of the developing solvent on the wafer and is usually from 10 to 300 seconds, more preferably from 20 to 120 seconds.

The temperature of the rinsing solution is preferably from 0 to 50° C., more preferably from 15 to 35° C.

The amount of the rinsing solution can be appropriately adjusted according to the rinsing method.

Also, after the development or rinsing, a treatment of removing the developer or rinsing solution adhering on the pattern with a supercritical fluid may be performed.

Furthermore, after the development, rinsing or treatment with a supercritical fluid, a heating treatment for removing the solvent remaining in the pattern may be performed. The heating temperature and heating time are not particularly limited as long as a good resist pattern can be obtained, but they are usually from 40 to 160° C. and from 10 seconds to 3 minutes. The heating treatment may be performed a plurality of times.

The present invention also relates to a nanoimprint mold and a photomask each produced by the resist pattern forming method of the present invention.

The nanoimprint mold and photomask are preferably produced using a resist-coated mask blank where a resist film obtained from the negative chemical-amplification resist composition of the present invention is coated on a mask blank.

In the case of forming a resist pattern on such a resist-coated mask blank by the resist pattern forming method of the present invention, the substrate used includes a transparent substrate such as quartz and calcium fluoride. In general, a light-shielding film, an antireflection film, further a phase shift film, and additionally a required functional film such as etching stopper film and etching mask film, are stacked on the substrate. As for the material of the functional film, a film containing silicon or a transition metal such as chromium, molybdenum, zirconium, tantalum, tungsten, titanium and niobium is stacked. Examples of the material used for the outermost surface layer include a material where the main constituent material is a material containing silicon or containing silicon and oxygen and/or nitrogen, a silicon compound material where the main constituent material is the material above which further contains a transition metal, and a transition metal compound material where the main constituent material is a material containing a transition metal, particularly, one or more transition metals selected from chromium, molybdenum, zirconium, tantalum, tungsten, titanium and niobium, or further containing one or more elements selected from oxygen, nitrogen and carbon.

The light-shielding film may have a single-layer structure but preferably has a multilayer structure where a plurality of materials are coated one on another. In the case of a multilayer structure, the film thickness per layer is not particularly limited but is preferably from 5 to 100 nm, more preferably from 10 to 80 nm. The thickness of the entire light-shielding film is not particularly limited but is preferably from 5 to 200 nm, more preferably from 10 to 150 nm.

This resist film is then subjected to exposure and development, whereby a resist pattern is obtained. An etching treatment or the like is appropriately performed by using the obtained resist pattern as a mask to produce a nanoimprint mold or a photomask.

The photomask of the present invention may be a light-transmitting mask used with an ArF excimer laser or the like, or a light-reflecting mask used in reflection lithography using EUV light as the light source.

Incidentally, the process when preparing an imprint mold by using the composition of the present invention is described, for example, in Japanese Patent 4,109,085, JP-A-2008-162101, and Yoshihiko Hirai (compiler), Nanoimprint no Kiso to Gijutsu Kaihatsu•Oyo Tenkai—Nanoimprint no Kiban Gijutsu to Saishin no Gijutsu Tenkai (Basic and Technology Expansion•Application Development of Nanoimprint—Substrate Technology of Nanoimprint and Latest Technology Expansion), Frontier Shuppan.

### [Negative Chemical-Amplification Resist Composition]

The negative chemical-amplification resist composition capable of undergoing negative conversion by a crosslinking reaction, which is used in the pattern forming method of the present invention, is described below.

The negative chemical-amplification resist composition capable of undergoing negative conversion by a crosslinking reaction contains (A) a polymer compound having a repeating unit represented by formula (I), (B) a phenolic compound being capable of crosslinking the polymer compound (A) by the action of an acid and having two or more benzene rings and four or more alkoxymethyl groups, and (C) a compound capable of generating an acid upon irradiation with an actinic ray or radiation.

### [1] (A) Polymer Compound

The negative chemical-amplification resist composition according to the present invention contains (A) a polymer compound having a repeating unit represented by the following formula (I). Thanks to this configuration, the secondary electron generation efficiency in the electron beam or EUV exposure and the crosslinking efficiency in the exposed area can be excellent, and the solubility of the unexposed area for the above-described developer becomes appropriate.

Specifically, the crosslinking reaction in a hydroxybenzene ring with the later-described crosslinking agent proceeds using, as a reaction site, a carbon atom adjacent to the boding position of a hydroxyl group on the benzene ring. Accordingly, when as in formula (I), a hydroxyl group is present at a meta-position with respect to the bond of the benzene ring to the main chain, a para-position located on the outermost side with respect to the main chain serves as a reaction site and is susceptible to attack by the crosslinking agent. This is presumed to lead to an excellent crosslinking efficiency in the exposed area.

On the other hand, when in the repeating unit represented by formula (I), a hydroxyl group is present at a para-position with respect to the bond of the benzene ring to the main chain, for the reason above, a high crosslinking efficiency is not obtained and moreover, such a repeating unit has a higher polarity and a lower solubility for the above-described developer. On this account, in the case of using a resin having a repeating unit in which a hydroxyl group is present at a para-position with respect to the bond of the benzene ring to the main chain, the resolving power is low and LER is large, as a result, the resolution is poor.

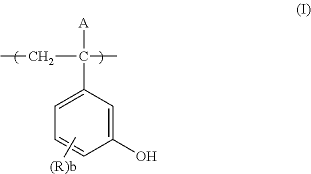

In formula (I), A represents a hydrogen atom, an alkyl group, a cycloalkyl group, a halogen atom or a cyano group.

R represents a halogen atom, an alkyl group, a cycloalkyl group, an aryl group, an alkenyl group, an aralkyl group, an alkoxy group, an alkylcarbonyloxy group or an alkylsulfonyloxy group, and when a plurality of Rs are present, each R may be the same as or different from every other R.

b represents an integer of 0 to 2. b is preferably 0 or 1, more preferably 0.

In formula (I), the alkyl group as A may further have a substituent and is preferably an alkyl group having a carbon number of 1 to 3. The cycloalkyl group as A may further has a substituent and may be monocyclic or polycyclic, and a cycloalkyl group having a carbon number of 5 to 10 is preferred. Examples of the halogen atom as A include Cl, Br and F. A is preferably a hydrogen atom or an alkyl group having a carbon number of 1 to 3 (e.g., methyl group, ethyl group), more preferably a hydrogen atom or a methyl group.

R is a halogen atom, an alkyl group, a cycloalkyl group, an aryl group, an alkenyl group, an aralkyl group, an alkoxy group, an alkylcarbonyloxy group or an alkylsulfonyloxy group and may further have a substituent. Examples of the halogen atom as R include Cl, Br, F and I. In the case of having a plurality of Rs, they may combine with each other to form a ring (preferably a 5- or 6-membered ring).

R is preferably a halogen atom, a linear or branched alkyl group having a carbon number of 1 to 8, which may have a substituent, a cycloalkyl group having a carbon number of 5 to 10, which may have a substituent, an aryl group having a carbon number of 6 to 15, which may have a substituent, an alkenyl group having a carbon number of 2 to 8, which may have a substituent, an aralkyl group having a carbon number of 7 to 16, which may have a substituent, an alkoxy group having a carbon number of 1 to 8, which may have a substituent, an alkylcarbonyloxy group having a carbon number of 2 to 8, which may have a substituent, or an alkylsulfonyloxy group having a carbon number of 1 to 8, which may have a substituent.

Each R is, independently, more preferably a halogen atom, an alkyl group having a carbon number of 1 to 4, which may have a substituent, an alkoxy group having a carbon number of 1 to 4, which may have a substituent, or an alkylcarbonyloxy group having a carbon number of 2 to 4, which may have a substituent, still more preferably a chlorine atom, a bromine atom, an iodine atom, an alkyl group having a carbon number of 1 to 3 (e.g., methyl group, ethyl group, propyl group, isopropyl group), or an alkoxy group having a carbon number of 1 to 3 (e.g., methoxy group, ethoxy group, propyloxy group, isopropyloxy group).

Examples of the substituent which A and R may further have include an alkyl group (e.g., methyl group, ethyl group, propyl group, isopropyl group, butyl group, tert-butyl group, hexyl group), an aryl group (e.g., phenyl group, naphthyl group), an aralkyl group, a hydroxyl group, an alkoxy group (e.g., methoxy group, ethoxy group, butoxy group, octyloxy group, dodecyloxy group), an acyl group (e.g., acetyl group, propanoyl group, benzoyl group), and an oxo group. The substituent is preferably a substituent having a carbon number of 15 or less.

The resin (A) for use in the present invention may contain, together with the repeating unit represented by formula (I), at least one repeating unit represented by any one of formulae (III) to (V):

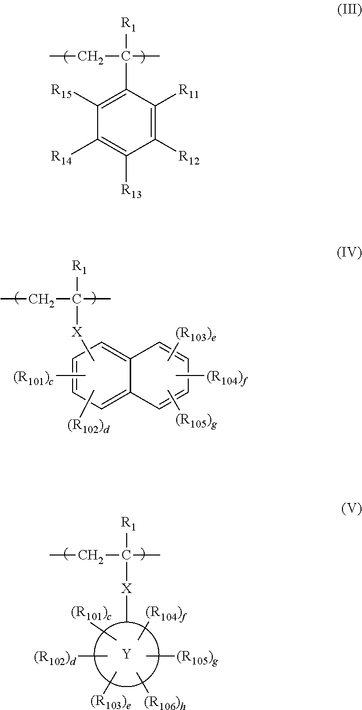

In formulae (III) to (V), R₁ represents a hydrogen atom, an alkyl group, a cycloalkyl group, a halogen atom, or a cyano group. Specific examples and preferred examples of the alkyl group, the cycloalkyl group and the halogen atom as R₁ are the same as those described for the alkyl group, the cycloalkyl group and the halogen atom in formula (I).

Preferred examples of R₁ are the same as preferred examples of R in formula (I).

X represents a single bond, a —COO— group, an —O— group or a —CON(R₁₆)— group, wherein R₁₆ represents a hydrogen or an alkyl group (preferably an alkyl group having a carbon number of 1 to 3, such as methyl group, ethyl group and propyl group). X is preferably a single bond, a —COO— group or a —CON(R₁₆)— group, more preferably a single bond or a —COO— group.

The ring structure of Y represents a tricyclic or higher polycyclic aromatic hydrocarbon ring structure and is preferably a structure represented by any one of the following structural formulae.

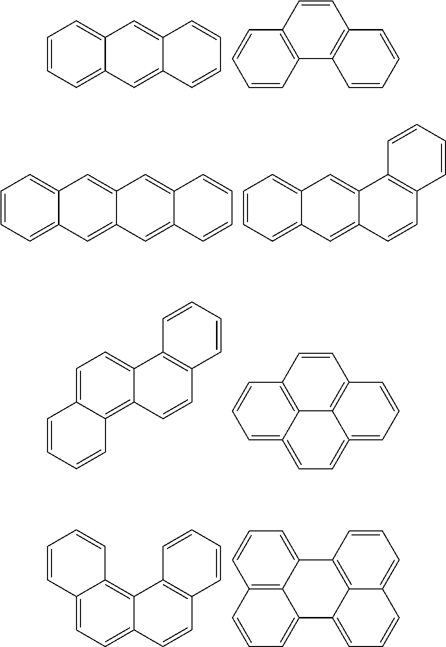

Each of R₁₁ to R₁₅ independently represents a hydrogen atom, a halogen atom, an alkyl group, a cycloalkyl group, an aryl group, an alkenyl group, an aralkyl group, an alkoxy group, an alkylcarbonyloxy group, an alkylsulfonyloxy group, an arylcarbonyloxy group, a nitro group or a cyano group. R₁₁ to R₁₅ may combine with each other to form a ring (preferably a 5- or 6-membered ring). Specific examples of the halogen atom, alkyl group, cycloalkyl group, aryl group, alkenyl group, aralkyl group, alkoxy group, alkylcarbonyloxy group and alkylsulfonyloxy group represented by R₁₁ to R₁₅ are the same as those for R in formula (I). The arylcarbonyloxy group represented by R₁₁ to R₁₅ is preferably an arylcarbonyloxy group having a carbon number of 7 to 16, which may have a substituent.

Each of R₁₀₁ to R₁₀₆ independently represents a hydroxy group, a halogen atom (e.g., Cl, Br, F, I), a linear or branched alkyl group having a carbon number of 1 to 8, which may have a substituent, a linear or branched alkoxy group having a carbon number of 1 to 8, which may have a substituent, a linear or branched alkylcarbonyloxy group having a carbon number of 2 to 8, which may have a substituent, a linear or branched alkylsulfonyloxy group having a carbon number of 1 to 8, which may have a substituent, an alkenyl group having a carbon number of 1 to 8, which may have a substituent, an aryl group having a carbon number of 6 to 15, which may have a substituent, an aralkyl group having a carbon number of 7 to 16, which may have a substituent, a carboxy group, or a perfluoroalkyl group having a carbon number of 1 to 4, which may have a substituent.

Each of c to h independently represents an integer of 0 to 3.

Specific examples of the substituent for these groups are the same as those described above as examples of the substituent which R may further have in formula (I).

Each of R₁₀₁ to R₁₀₆ is, independently, preferably a halogen atom, an alkyl group having a carbon number of 1 to 4, which may have a substituent, an alkoxy group having a carbon number of 1 to 4, which may have a substituent, or an alkylcarbonyloxy group having a carbon number of 2 to 4, which may have a substituent, more preferably a chlorine atom, a bromine atom, an iodine atom, an alkyl group having a carbon number of 1 to 3 (e.g., methyl group, ethyl group, propyl group, isopropyl group), an alkoxy group having a carbon number of 1 to 3 (e.g., methoxy group, ethoxy group, propyloxy group, isopropyloxy group), or an alkylcarbonyloxy group having a carbon number of 2 or 3 (e.g., acetoxy group, propionyloxy group).

In the case where each of R₁₀₁ to R₁₀₆ combines with a carbon atom in the main chain to form a ring structure, the ring structure formed is preferably a 4- to 6-membered ring.

Each of c to h independently represents preferably 0 or 1, more preferably 0.

The resin (A) for use in the present invention may be any of a resin having only one repeating unit represented by formula (I), a resin having two or more repeating units represented by formula (I), and a resin having a repeating unit represented by formula (I) and at least one repeating unit represented by any one of formulae (III) to (V), and other polymerizable monomers capable of controlling the film-forming property or solvent solubility may be also copolymerized therein.

Examples of such a polymerizable monomer include, but are not limited to, a styrene, an alkyl-substituted styrene, an alkoxystyrene, an acyloxystyrene, a hydrogenated hydroxystyrene, a maleic anhydride, an acrylic acid derivative (e.g., acrylic acid, acrylic acid ester), a methacrylic acid derivative (e.g., methacrylic acid, methacrylic acid ester), an N-substituted maleimide, an acrylonitrile, and a methacrylonitrile.

In addition, other than the above, preferred examples of the repeating unit of the resin also include a unit having a cyclic structure in the main chain (for example, a unit derived from a monomer having an indene structure), a unit having a naphthol structure, and a repeating unit having a —C(CF₃)₂OH group.

In the present invention, as for the resin (A), one resin may be used alone, or two or more resins may be used in combination.

The resin (A) may be composed of only the repeating unit represented by formula (I) or may contain a repeating unit other than the repeating unit represented by formula (I), but in the case of containing a repeating unit other than the repeating unit represented by formula (I), the content of the repeating unit represented by formula (I) in the resin (A) is generally from 50 to 99.5 mol %, preferably from 70 to 99 mol %.

Also, in the case where the resin (A) contains a repeating unit other than the repeating unit represented by formula (I), the ratio between the repeating unit represented by formula (I) and the repeating unit represented by formulae (III) to (V) is, in terms of the molar ratio, preferably from 99/1 to 50/50, more preferably from 99/1 to 60/40, still more preferably 99/1 to 70/30.

The molecular weight of the resin (A) is, in terms of the mass average molecular weight, preferably from 1,000 to 50,000, more preferably from 2,000 to 10,000, still more preferably from 2,000 to 6,000.

The molecular weight distribution (Mw/Mn) of the resin (A) is preferably from 1.0 to 2.0, more preferably from 1.0 to 1.35.

Here, the molecular weight and molecular weight distribution of the resin are defined as a polystyrene-reduced value by GPC measurement.

The amount added of the resin (A) (in the case of using a plurality of resins in combination, the total amount) is from 30 to 95 mass %, preferably from 40 to 90 mass %, more preferably from 50 to 80 mass %, based on the entire solid content of the composition.

The resin (A) can be synthesized by a known radical polymerization method or anionic polymerization method. For example, in the radical polymerization method, a vinyl monomer is dissolved in an appropriate organic solvent, and the reaction is allowed to proceed at room temperature or under heating by using a peroxide (e.g., benzoyl peroxide), a nitrile compound (e.g., azobisisobutyronitrile) or a redox compound (e.g., cumene hydroperoxide-ferrous salt) as the initiator, whereby the polymer can be obtained. In the anionic polymerization method, a vinyl monomer is dissolved in an appropriate organic solvent, and the reaction is allowed to proceed usually under cooling by using a metal compound (e.g., butyllithium) as the initiator, whereby the polymer can be obtained.

Specific examples of the resin (A) for use in the present invention are illustrated below, but the present invention is not limited thereto.

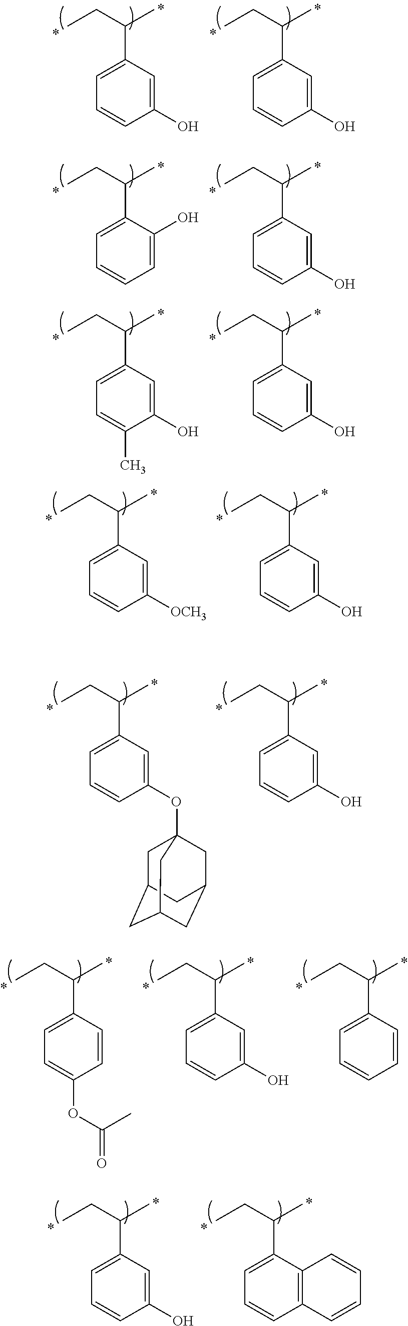

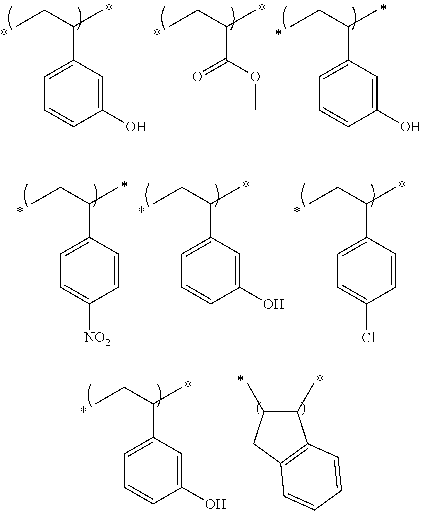

[2] (B) Phenolic Compound being Capable of Crosslinking the Polymer Compound (A) by the Action of an Acid and Having Two or More Benzene Rings and Four or More Alkoxymethyl Groups

In the negative chemical-amplification resist composition according to the present invention, a phenolic compound being capable of crosslinking the polymer compound (A) by the action of an acid and having two or more benzene rings and four or more alkoxymethyl groups (hereinafter, referred to as “crosslinking agent (B)”) is used as the crosslinking agent. Here, the alkoxymethyl group acts as a crosslinking group. As the crosslinking agent (B), known crosslinking agents can be effectively used.

If the number of benzene rings in the crosslinking agent is 1 or less, the secondary electron generation efficiency is low and the crosslinking reaction does not sufficiently proceed, giving rise to low resolving power. Also, the solubility of such a crosslinking agent for the developer used in the present invention tends to be excessively high compared with the solubility of the polymer compound similarly used in the present invention. In such a case, the crosslinking agent remaining still unreacted in the exposed area works out to a penetration channel for the developer and swelling of the resist pattern readily occurs, as a result, the resolution is impaired.

If the number of alkoxymethyl groups in the crosslinking agent is 3 or less, the crosslinking efficiency in the exposed area is low and therefore, the developer readily penetrates into the resist pattern, giving rise to low resolving power and large LER, as a result, the resolution is poor.

The crosslinking agent (B) is preferably a phenolic compound having three or more benzene rings and from 4 to 8 alkoxymethyl groups.

Furthermore, it is more preferred that the crosslinking agent (B) has from 4 to 6 alkoxymethyl groups.

Among crosslinking agents (B), particularly preferred compounds are illustrated below. In the formulae, L¹ to L⁸, which may be the same or different, represent an alkoxymethyl group, and the alkoxymethyl group is preferably a methoxymethyl group or an ethoxymethyl group, more preferably a methoxymethyl group.

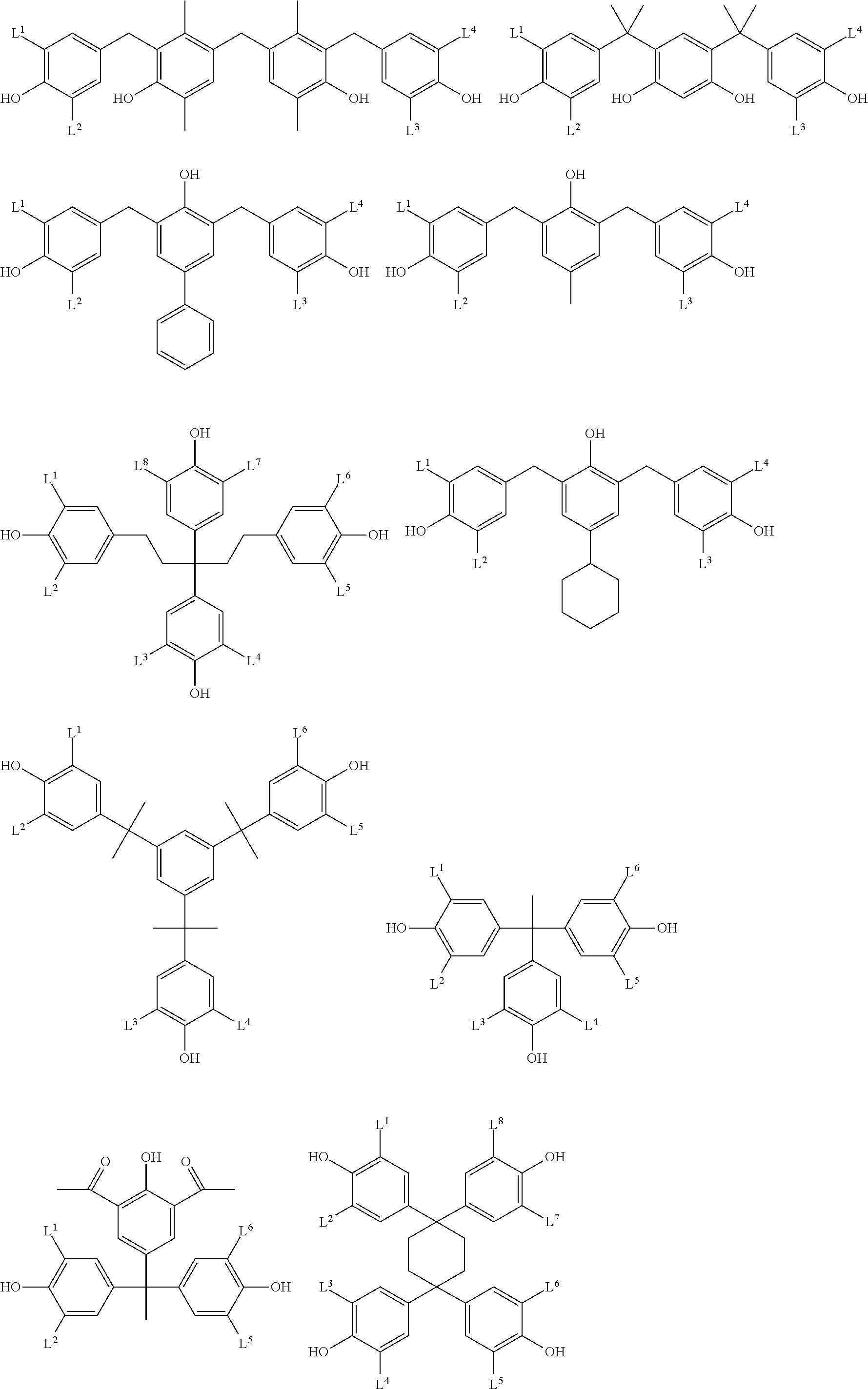

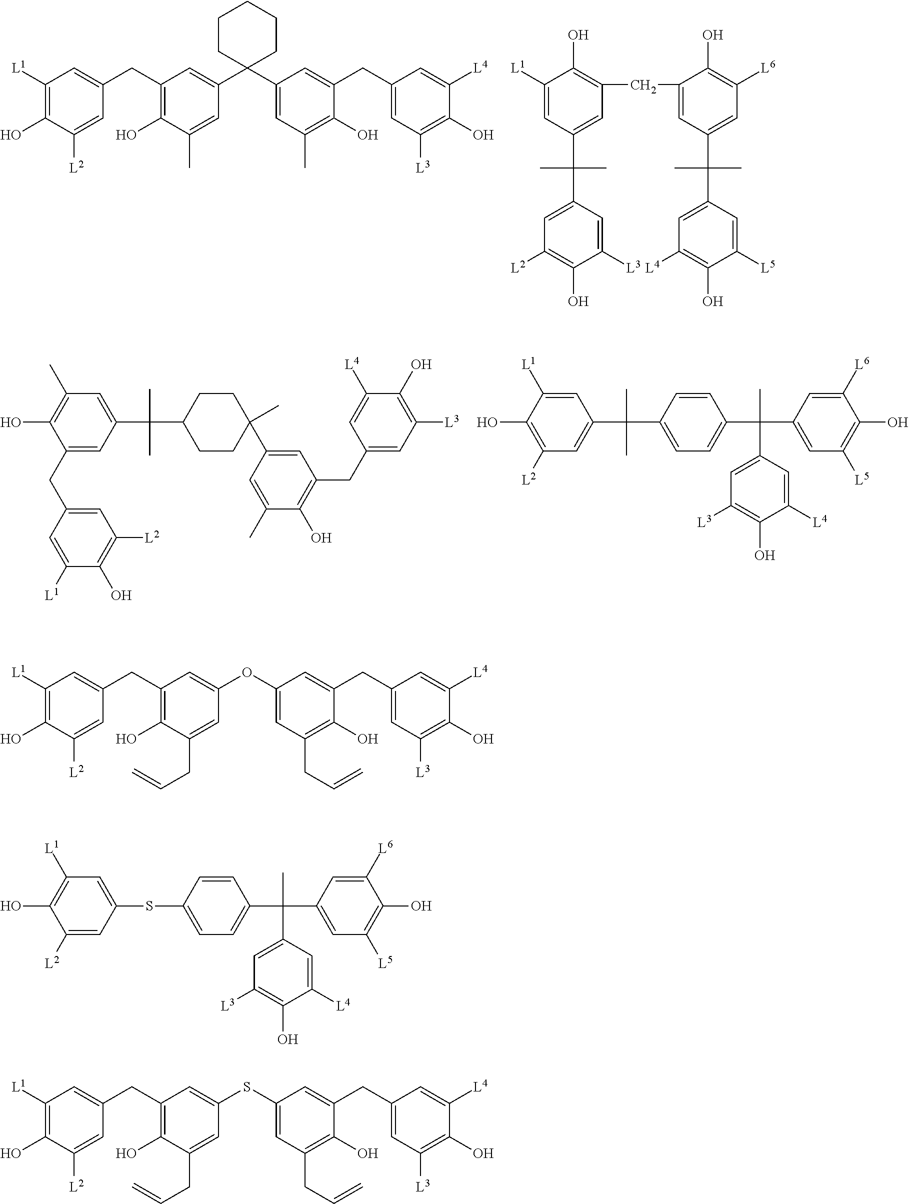

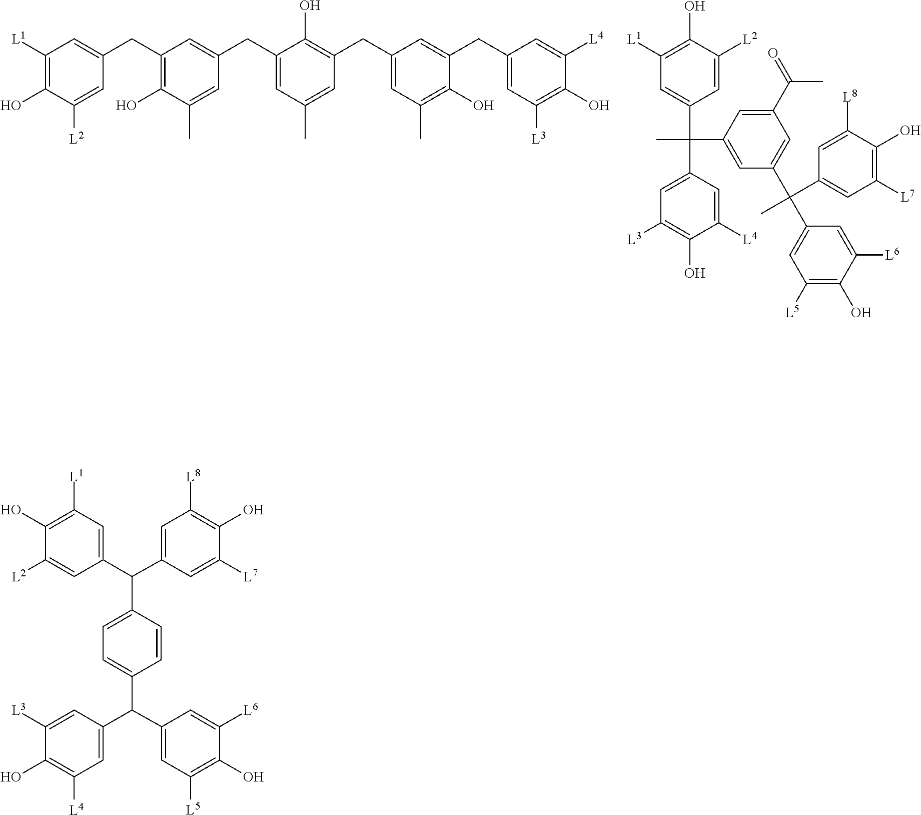

From the standpoint of preventing reduction in the residual film ratio and resolving power and at the same time, keeping good stability of the resist solution during storage, the crosslinking agent (B) is used in an added amount of preferably from 3 to 65 mass %, more preferably from 5 to 50 mass %, still more preferably from 10 to 45 mass %, based on the entire solid content of the resist composition.

In the present invention, one crosslinking agent may be used alone, or two or more crosslinking agents may be used in combination. For example, in the case of using another crosslinking agent in combination, in addition to the crosslinking agent (B), the ratio between the crosslinking agent (B) and another crosslinking agent is, in terms of molar ratio, from 99/1 to 20/80, preferably from 90/10 to 40/60, more preferably from 80/20 to 50/50.

[3] (C) Compound Capable of Generating an Acid Upon Irradiation with an Actinic Ray or Radiation

The negative chemical-amplification resist composition of the present invention contains (C) a compound capable of generating an acid upon irradiation with an actinic ray or radiation (hereinafter, sometimes referred to as “acid generator”).

The acid generator is preferably a compound capable of generating an organic acid, for example, at least any of a sulfonic acid, a bis(alkylsulfonyl)imide and a tris(alkylsulfonyl)methide, upon irradiation with an actinic ray or radiation.

More preferred are compounds represented by the following formulae (ZI), (ZII) and

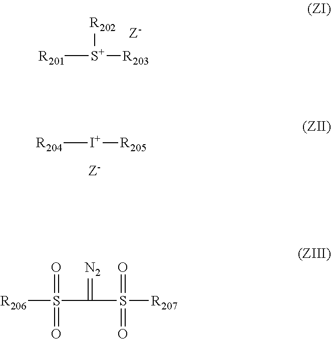

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Examples of the organic group of R₂₀₁, R₂₀₂ and R₂₀₃ include an aryl group, an alkyl group, and a cycloalkyl group.

The aryl group of R₂₀₁, R₂₀₂ and R₂₀₃ is an aryl group having a carbon number of usually from 6 to 20, preferably from 6 to 10, more preferably a phenyl group or a naphthyl group, still more preferably a phenyl group. The aryl group may be an aryl group having a heterocyclic structure containing an oxygen atom, a nitrogen atom, a sulfur atom or the like. Examples of the heterocyclic structure include pyrrole, furan, thiophene, indole, benzofuran, and benzothiophene.

The alkyl group and cycloalkyl group of R₂₀₁, R₂₀₂ and R₂₀₃ are preferably a linear or branched alkyl group having a carbon number of 1 to 10 and a cycloalkyl group having a carbon number of 3 to 10. The alkyl group is more preferably a 2-oxoalkyl group or an alkoxycarbonylmethyl group. The cycloalkyl group is more preferably a 2-oxocycloalkyl group.

The 2-oxoalkyl group may be either linear or branched and is preferably a group having >C═O at the 2-position of the above-described alkyl group.

The 2-oxocycloalkyl group is preferably a group having >C═O at the 2-position of the above-described cycloalkyl group.

Each of R₂₀₁, R₂₀₂ and R₂₀₃ may be further substituted with a halogen atom, an alkoxy group (for example, having a carbon number of 1 to 5), a hydroxyl group, a cyano group, a nitro group or the like.

Two members out of R₂₀₁ to R₂₀₃ may combine to form a ring structure (preferably a 3- to 15-membered ring), and the ring may contain an oxygen atom, a sulfur atom, an ester bond, an amide bond or a carbonyl group. The group formed by combining two members out of R₂₀₁ to R₂₀₃ includes an alkylene group (e.g., butylenes group, pentylene group).

Z⁻ represents a non-nucleophilic anion (an anion having an extremely low ability of causing a nucleophilic reaction).

Examples of the non-nucleophilic anion include a sulfonate anion (such as aliphatic sulfonate anion, aromatic sulfonate anion and camphorsulfonate anion), a carboxylate anion (such as aliphatic carboxylate anion, aromatic carboxylate anion and aralkylcarboxylate anion), a sulfonylimide anion, a bis(alkylsulfonyl)imide anion, and a tris(alkylsulfonyl)methide anion.

The aliphatic moiety in the aliphatic sulfonate anion and aliphatic carboxylate anion may be an alkyl group or a cycloalkyl group but is preferably a linear or branched alkyl group having a carbon number of 1 to 30 or a cycloalkyl group having a carbon number of 3 to 30.

The aromatic group in the aromatic sulfonate anion and aromatic carboxylate anion is preferably an aryl group having a carbon number of 6 to 14, and examples thereof include a phenyl group, a tolyl group, and a naphthyl group.

The alkyl group, cycloalkyl group and aryl group in the aliphatic sulfonate anion and aromatic sulfonate anion may have a substituent. Specific examples thereof include a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 2 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of 5 to 20), and a cycloalkylalkyloxyalkyloxy group (preferably having a carbon number of 8 to 20).

The aryl group and ring structure in each group may further have, as a substituent, an alkyl group (preferably having a carbon number of 1 to 15) or a cycloalkyl group (preferably having a carbon number of 3 to 15).

The aralkyl group in the aralkylcarboxylate anion is preferably an aralkyl group having a carbon number of 6 to 12, and examples thereof include a benzyl group, a phenethyl group, a naphthylmethyl group, a naphthylethyl group, and a naphthylbutyl group.

Examples of the sulfonylimide anion include saccharin anion.

The alkyl group in the bis(alkylsulfonyl)imide anion and tris(alkylsulfonyl)methide anion is preferably an alkyl group having a carbon number of 1 to 5, and examples of the substituent on this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom and a fluorine atom-substituted alkyl group being preferred.

Also, the alkyl groups in the bis(alkylsulfonyl)imide anion may combine with each other to form a ring structure. In this case, the acid strength increases.

Other examples of the non-nucleophilic anion include fluorinated phosphorus (e.g., PF₆⁻), fluorinated boron (e.g., BF₄⁻), and fluorinated antimony (e.g., SbF₆⁻).

The non-nucleophilic anion is preferably an aliphatic sulfonate anion substituted with a fluorine atom at least on the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion (more preferably having a carbon number of 4 to 8) or a fluorine atom-containing benzenesulfonate anion, still more preferably nonafluorobutanesulfonate anion, perfluorooctanesulfonate anion, pentafluorobenzenesulfonate anion, or 3,5-bis(trifluoromethyl)benzenesulfonate anion.

As regards the acid strength, the pKa of the acid generated is preferably −1 or less for enhancing the sensitivity.

An anion represented by the following formula (AN1) is also a preferred embodiment of the non-nucleophilic anion:

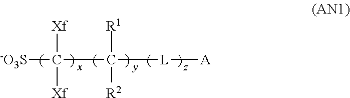

In the formula, each Xf independently represents a fluorine atom or an alkyl group substituted with at least one fluorine atom.

Each of R¹ and R² independently represents a group selected from a hydrogen atom, a fluorine atom and an alkyl group, and when a plurality of R¹s or R²s are present, each R¹ or R² may be the same as or different from every other R¹ or R².

L represents a divalent linking group, and when a plurality of Ls are present, each L may be the same as or different from every other L.

A represents a cyclic organic group.

x represents an integer of 1 to 20, y represents an integer of 0 to 10, and z represents an integer of 0 to 10.

Formula (AN1) is described in more detail.

The alkyl group in the fluorine atom-substituted alkyl group of Xf is preferably an alkyl group having a carbon number of 1 to 10, more preferably a carbon number of 1 to 4. Also, the fluorine atom-substituted alkyl group of Xf is preferably a perfluoroalkyl group.

Xf is preferably a fluorine atom or a perfluoroalkyl group having a carbon number of 1 to 4. Specific examples of Xf include a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, with a fluorine atom and CF₃ being preferred. In particular, it is preferred that both Xfs are a fluorine atom.

The alkyl group of R¹ and R² may have a substituent (preferably a fluorine atom) and is preferably an alkyl group having a carbon number of 1 to 4, more preferably a perfluoroalkyl group having a carbon number of 1 to 4. Specific examples of the alkyl group having a substituent of R¹ and R² include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, with CF₃ being preferred.

Each of R¹ and R² is preferably a fluorine atom or CF₃.

x is preferably an integer of 1 to 10, more preferably from 1 to 5.

y is preferably an integer of 0 to 4, more preferably 0.

z is preferably an integer of 0 to 5, more preferably from 0 to 3.

The divalent linking group of L is not particularly limited and examples thereof includes —COO—, —COO—, —CO—, —O—, —S—, —SO—, —SO₂—, an alkylene group, a cycloalkylene group, an alkenylene group, and a linking group formed by combining a plurality of these groups. A linking group having a total carbon number of 12 or less is preferred. Among these, —COO—, —COO—, —CO—, —O— and —SO₂— are preferred, and —COO—, —COO— and —SO₂— are more preferred.

The cyclic organic group of A is not particularly limited, and examples thereof include an alicyclic group, an aryl group, and a heterocyclic group (including not only those having aromaticity but also those having no aromaticity).

The alicyclic group may be monocyclic or polycyclic and is preferably a monocyclic cycloalkyl group such as cyclopentyl group, cyclohexyl group and cyclooctyl group, or a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint that the diffusion in the film during heating after exposure can be suppressed and MEEF can be improved.

Examples of the aryl group include a benzene ring, a naphthalene ring, a phenanthrene ring, and an anthracene ring.

Examples of the heterocyclic group include a group derived from a furan ring, a thiophene ring, a benzofuran ring, a benzothiophene ring, a dibenzofuran ring, a dibenzothiophene ring, a pyridine ring, and a piperidine ring. Among these, those derived from a furan ring, a thiophene ring, a pyridine ring and a piperidine ring are preferred. The above-described cyclic organic group may have a substituent, and examples of the substituent include an alkyl group (may be linear or branched; preferably having a carbon number of 1 to 12), a cycloalkyl group (may be monocyclic, polycyclic or spirocyclic; preferably having a carbon number of 3 to 20), an aryl group (preferably having a carbon number of 6 to 14), a hydroxy group, an alkoxy group (preferably having a carbon number of 1 to 12), a ureido group, a sulfonamido group (preferably having a carbon number of 0 to 12), and a group (preferably having a carbon number of 1 to 12) having an ester group, an amido group, a urethane group, a thioether group or a sulfonic acid ester group. Incidentally, the carbon constituting the cyclic organic group (the carbon contributing to ring formation) may be carbonyl carbon.

Among R₂₀₁, R₂₀₂ and R₂₀₃, at least one of R₂₀₁, R₂₀₂ and R₂₀₃ is preferably an aryl group, and it is more preferred that those three members all are an aryl group. The aryl group may be, for example, a phenyl group or a naphthyl group and may be also a heteroaryl group such as indole residue and pyrrole residue. These aryl groups may further have a substituent, and examples of the substituent include, but are not limited to, a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), and an alkoxycarbonyloxy group (preferably having a carbon number of 2 to 7).

In the case where two members out of R₂₀₁ to R₂₀₃ are combined to form a ring structure, the ring structure is preferably a structure represented by the following formula (A1):

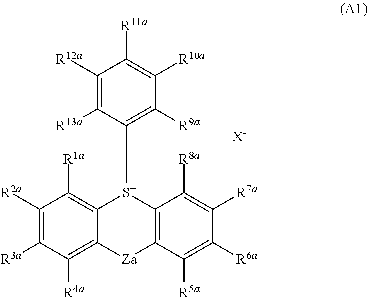

In formula (A1), each of R^{1a} to R^{13a} independently represents a hydrogen atom, a halogen atom, a nitro group, or an organic group.

From one to three members out of R^{1a} to R^{13a} are preferably not a hydrogen atom, and it is more preferred that any one of R^{9a} to R^{13a} is not a hydrogen atom.

Za represents a single bond or a divalent linking group.

X⁻ has the same meaning as Z⁻ in formula (ZI).

Specific examples of R^{1a} to R^{13a} when these are not a hydrogen atom include a halogen atom, a nitro group, a linear, branched or cyclic alkyl group, an alkenyl group, an alkynyl group, an aryl group, a heterocyclic group, a cyano group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an acylamino group, an aminocarbonylamino group, an alkoxycarbonylamino group, an aryloxycarbonylamino group, a sulfamoylamino group, an alkylsulfonylamino group, an arylsulfonylamino group, an alkylthio group, an arylthio group, a heterocyclic thio group, an alkylsulfinyl group, an arylsulfinyl group, an alkylsulfonyl group, an arylsulfonyl group, an acyl group, an aryloxycarbonyl group, an alkoxycarbonyl group, a carbamoyl group, an arylazo group, a heterocyclic azo group, a phosphinylamino group, a silyl group, a ureido group, and other known organic groups.

R^{1a} to R^{13a} are, when these are not a hydrogen atom, preferably a linear, branched or cyclic alkyl group substituted with a hydroxyl group.

Examples of the divalent linking group of Za include an alkylene group, an arylene group, a carbonyl group, a sulfonyl group, a carbonyloxy group, a carbonylamino group, a sulfonylamide group, —O—, —S—, an amino group, a disulfide group, —(CH₂)ₙ—CO—, —(CH₂)ₙ—SO₂—, —CH═CH—, an aminocarbonylamino group, and an aminosulfonylamino group (n is an integer of 1 to 3).

Incidentally, preferred examples of the structure where at least one of R₂₀₁, R₂₀₂ and R₂₀₃ is not an aryl group include a cation structure such as compounds described in paragraphs 0046 and 0047 of JP-A-2004-233661 and paragraphs 0040 to 0046 of JP-A-2003-35948, compounds illustrated as formulae (I-1) to (1-70) in U.S. Patent Application Publication No. 2003/0224288A1, and compounds illustrated as formulae (IA-1) to (IA-54) and formulae (IB-1) to (IB-24) in U.S. Patent Application Publication No. 200310077540A1.

In formulae (ZII) and (ZIII), each of R₂₀₄ to R₂₀₇ independently represents an aryl group, an alkyl group or a cycloalkyl group.

The aryl group, alkyl group and cycloalkyl group of R₂₀₄ to R₂₀₇ are the same as the aryl group, alkyl group and cycloalkyl group of R₂₀₁ to R₂₀₃ in the compound (ZI).

The aryl group, alkyl group and cycloalkyl group of R₂₀₄ to R₂₀₇ may have a substituent. Examples of the substituent include those of the substituent which the aryl group, alkyl group and cycloalkyl group of R₂₀₁ to R₂₀₃ in the compound (ZI) may have.

Z⁻ represents a non-nucleophilic anion, and examples thereof are the same as those of the non-nucleophilic anion of T in formula (ZI).

The acid generator further includes compounds represented by the following formulae (ZIV), (ZV) and (ZVI):

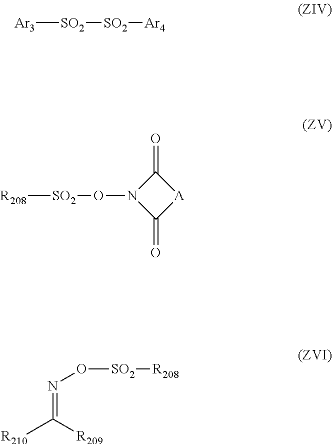

In formulae (ZIV) to (ZVI), each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group of R₂₀₁, R₂₀₂ and R₂₀₃ in formula (ZI).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI).

The alkylene group of A includes an alkylene group having a carbon number of 1 to 12 (e.g., methylene group, ethylene group, propylene group, isopropylene group, butylenes group, isobutylene group), the alkenylene group of A includes an alkenylene group having a carbon number of 2 to 12 (e.g., ethynylene group, propenylene group, butenylene group), and the arylene group of A includes an arylene group having a carbon number of 6 to 10 (e.g., phenylene group, tolylene group, naphthylene group).

Out of the acid generators, particularly preferred examples are illustrated below.

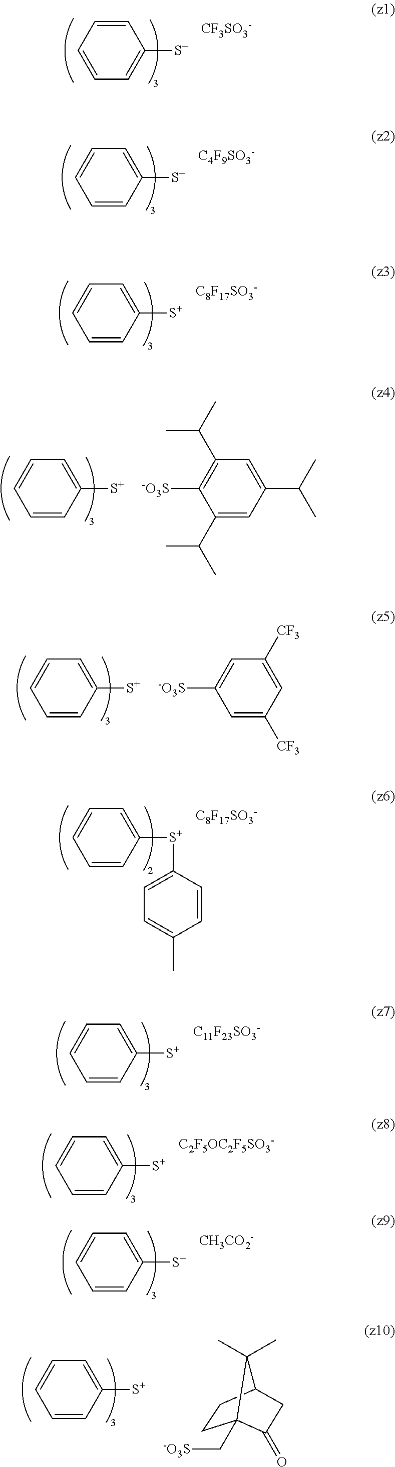

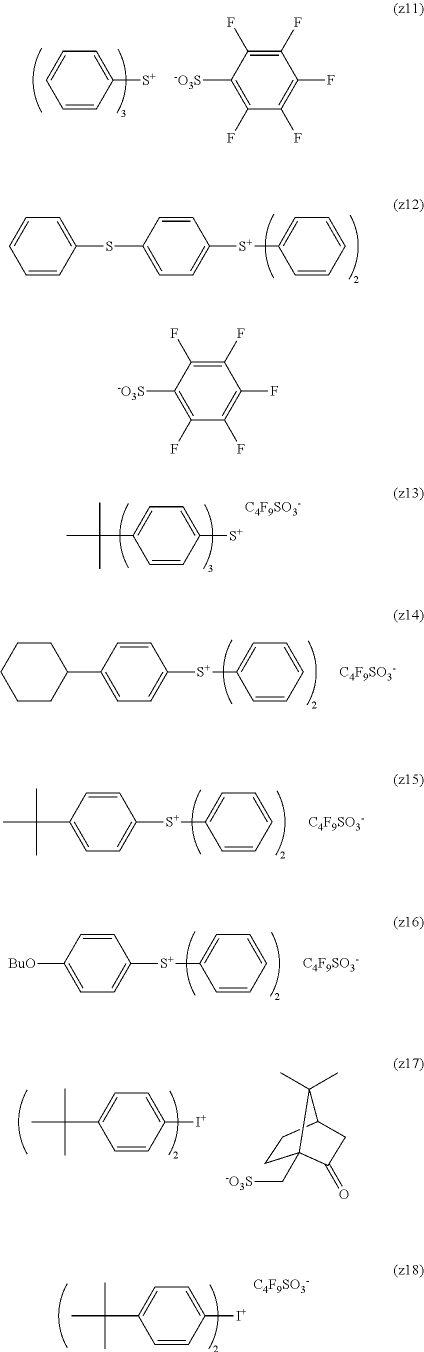

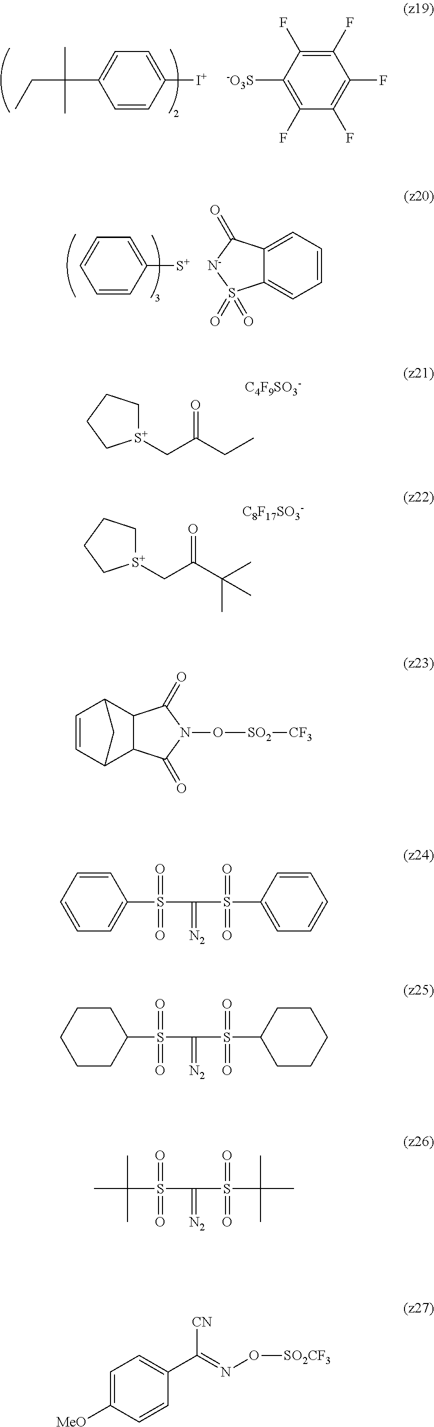

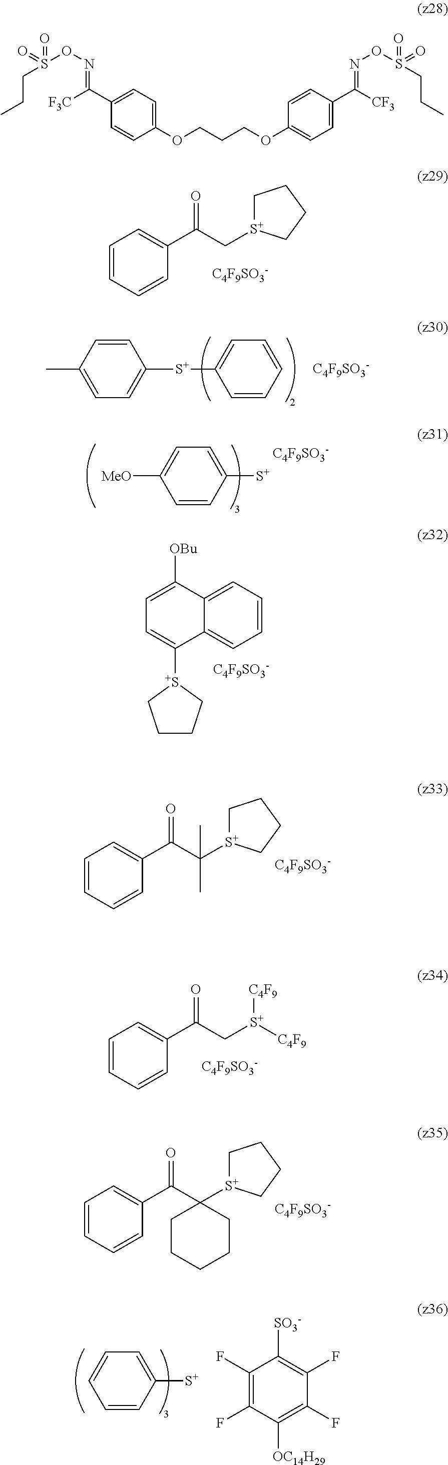

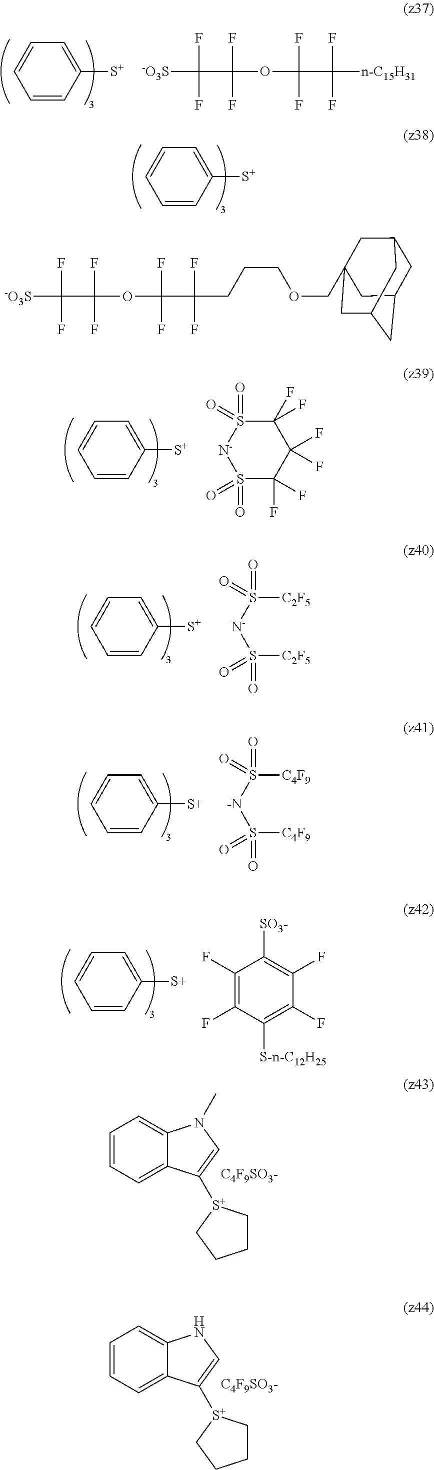

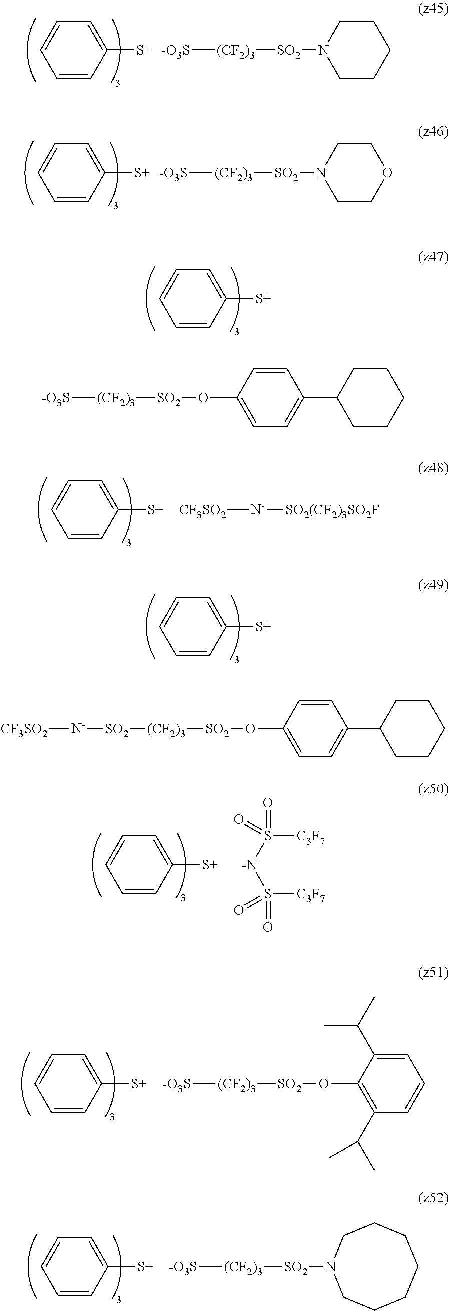

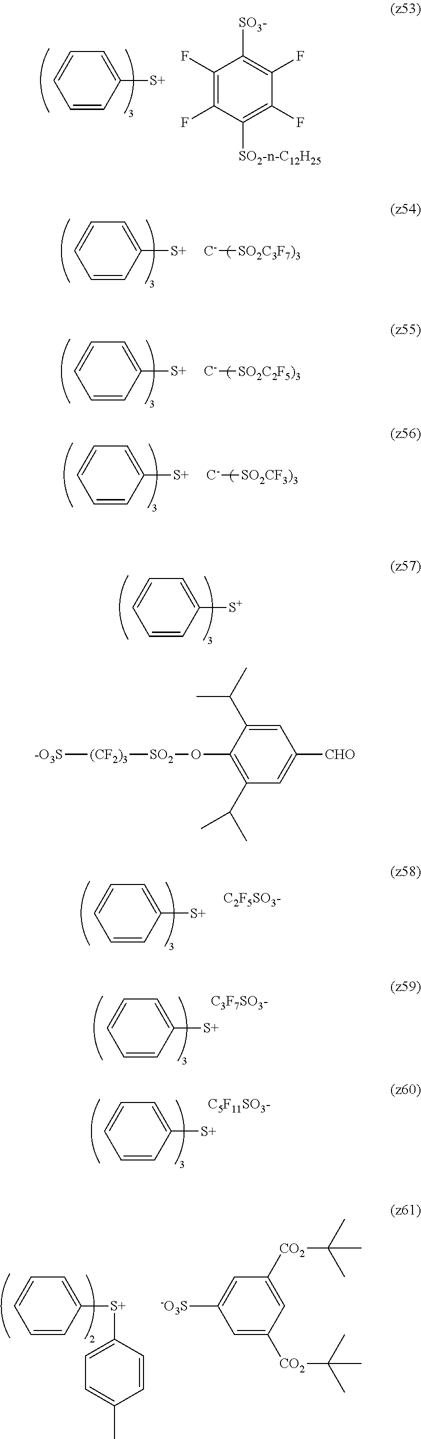

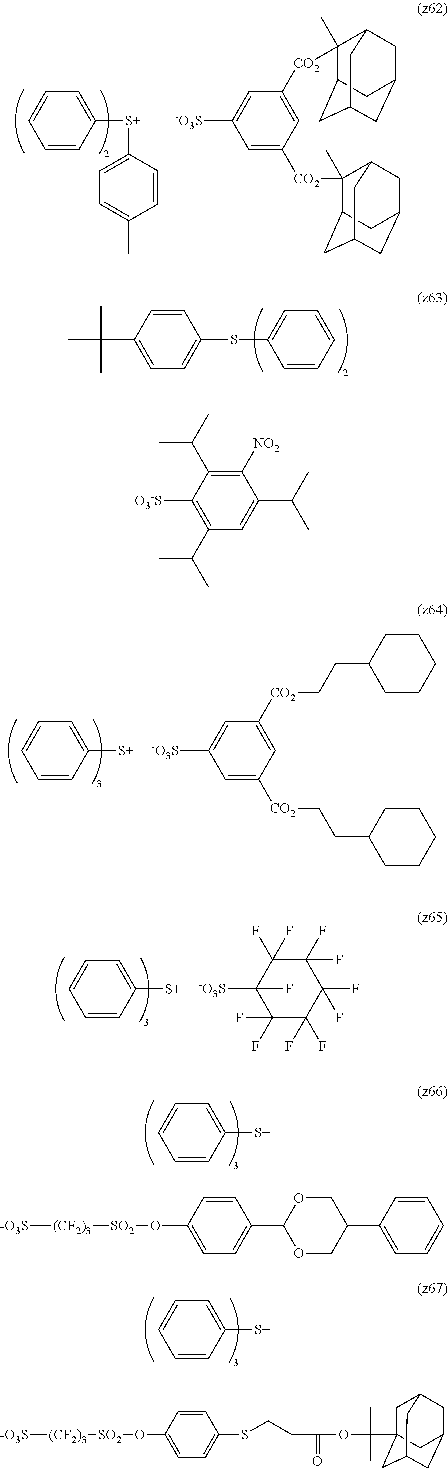

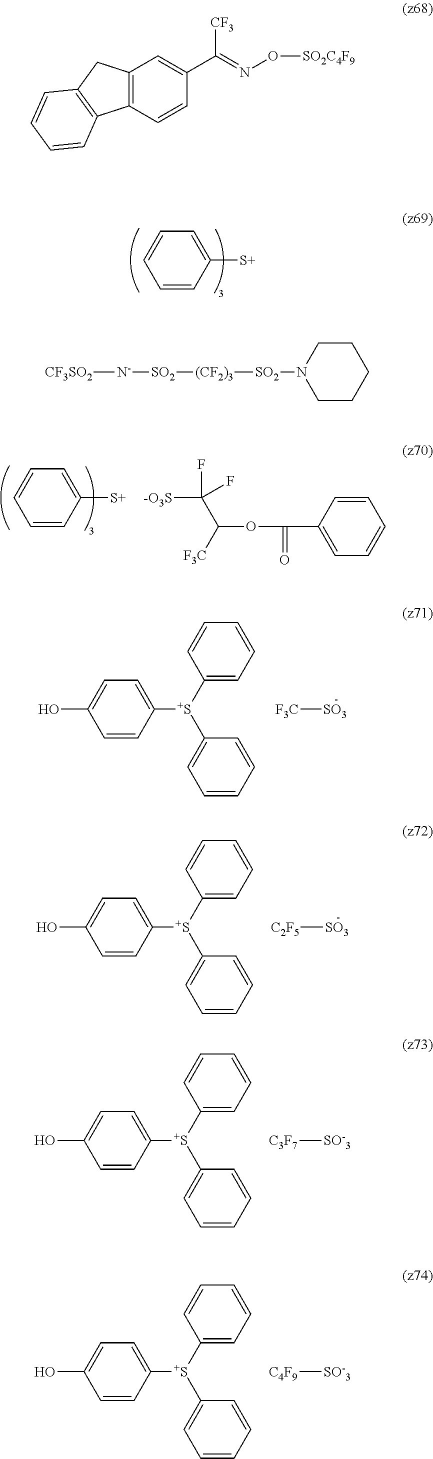

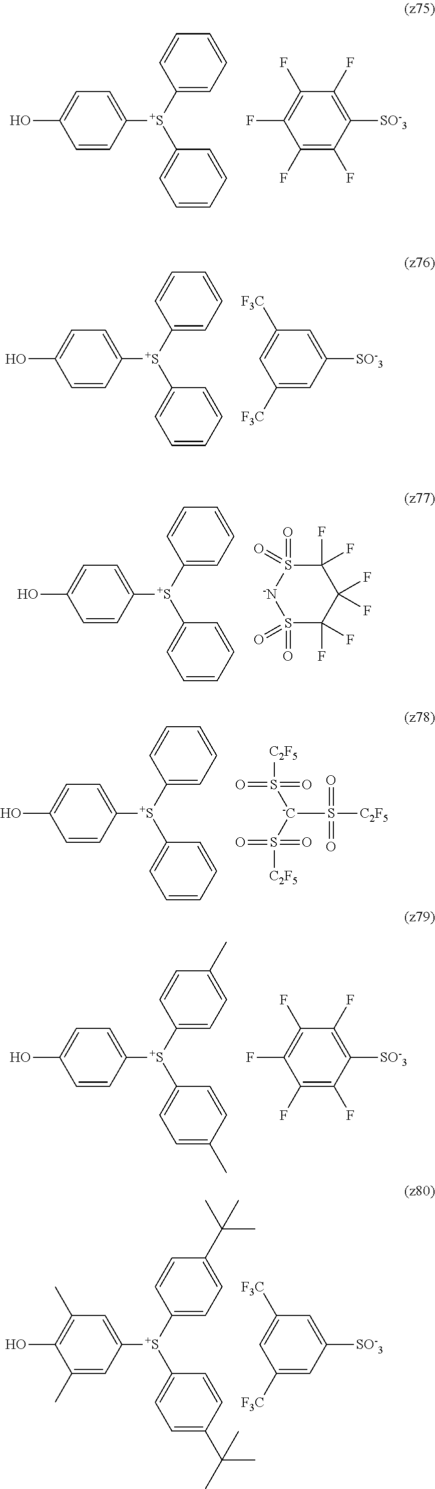

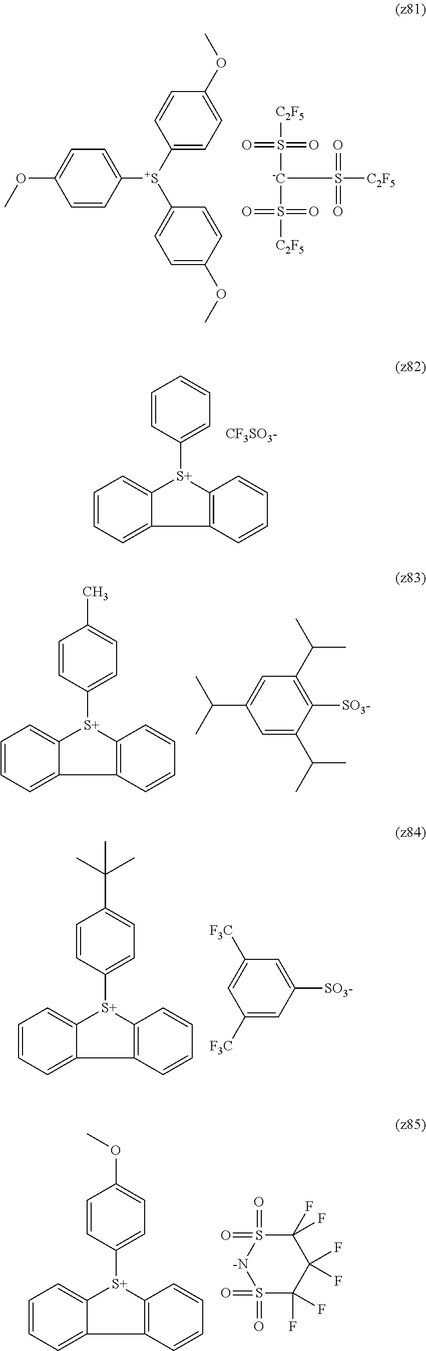

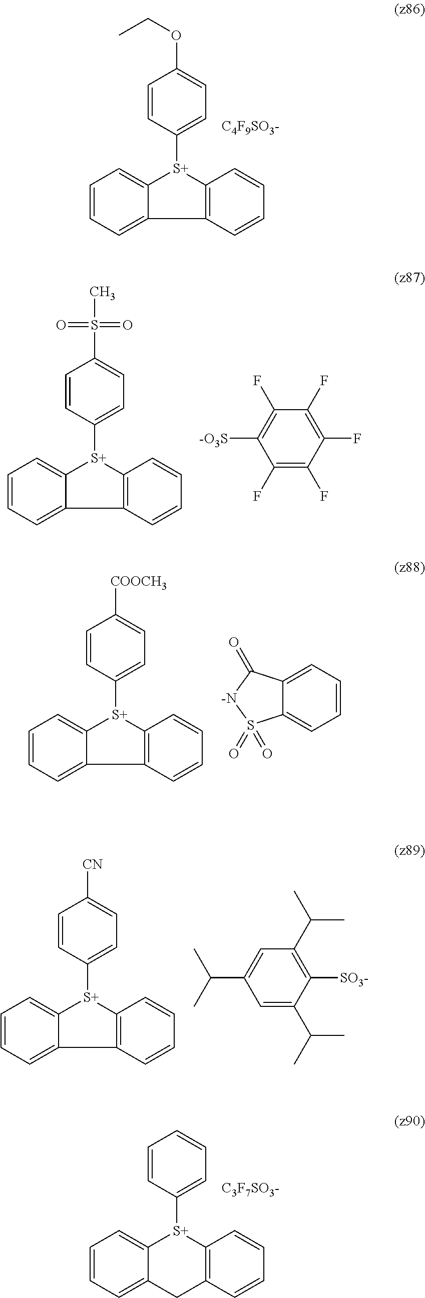

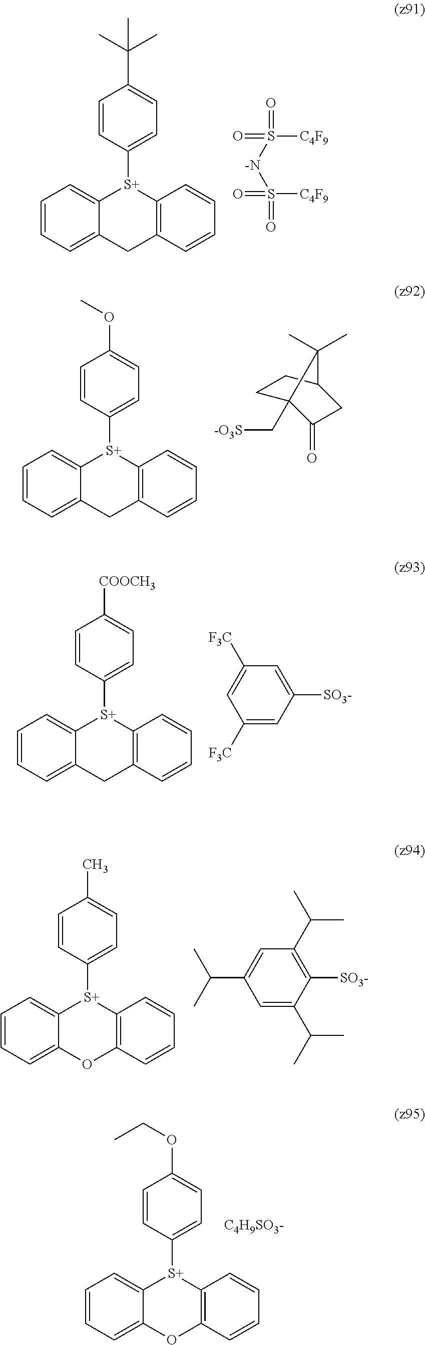

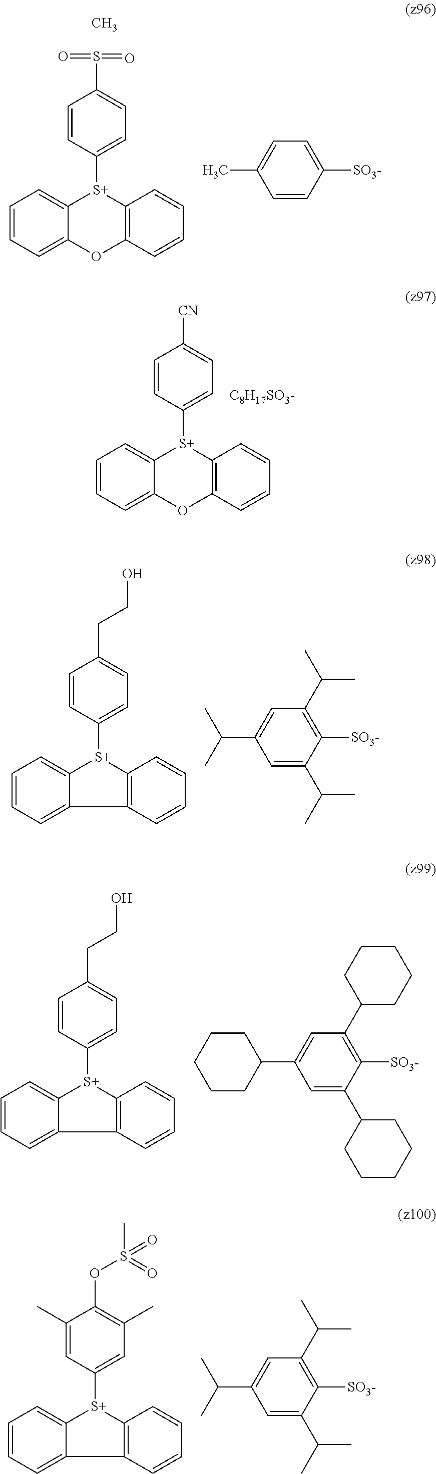

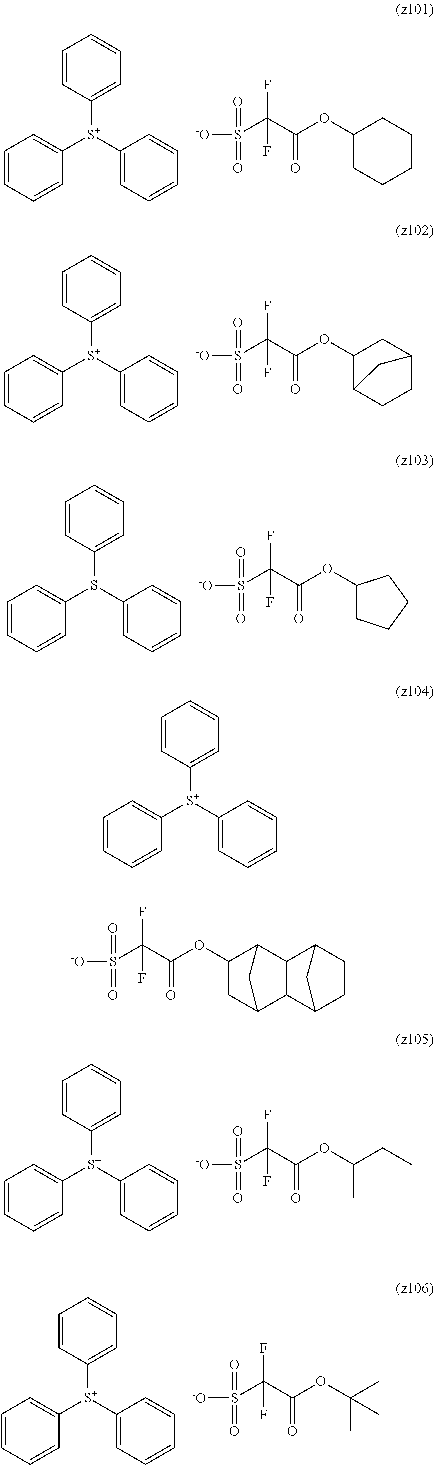

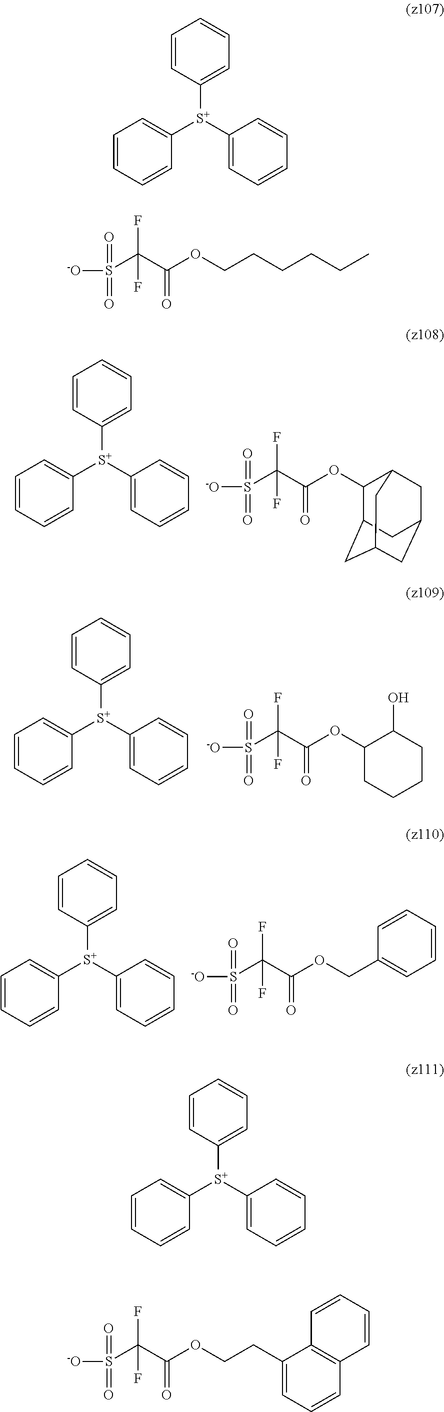

As for the acid generator, one kind of an acid generator may be used alone, or two or more kinds of acid generators may be used in combination. In the case of using two or more kinds of acid generators in combination, preferred are, for example, (1) an embodiment where two kinds of PAGs differing in the acid strength are used in combination, and (2) an embodiment where two kinds of acid generators differing in the size (molecular weight or carbon number) of the generated acid are used in combination.

Examples of the embodiment (1) include a combination use of a sulfonic acid generator having fluorine and a tris(fluoroalkylsulfonyl)methide acid generator, a combination use of a sulfonic acid generator having fluorine and a sulfonic acid generator having no fluorine, and a combination use of an alkylsulfonic acid generator and an arylsulfonic acid generator.

Examples of the embodiment (2) include a combination use of two kinds of acid generators differing in the carbon number of the generated acid anion by 4 or more.

The content of the acid generator (in the case of using a plurality of acid generators in combination, the total amount) in the composition is preferably from 1 to 30 mass %, more preferably from 5 to 25 mass %, still more preferably from 8 to 20 mass %, based on the entire solid content of the composition.

Also, the negative chemical-amplification resist composition preferably contains, as the acid generator (C), (C′) an ionic compound capable of generating an acid upon irradiation with an actinic ray or radiation, typified by the compound of formula (ZI) or (ZII) as above, in an amount of 9 mass % or more based on the entire solid content of the negative chemical-amplification resist composition. Thanks to this configuration, the contrast in concentration of the generated acid between the exposed area and the unexposed area can be increased and therefore, the resolution is enhanced.

### [4] Basic Compound

The negative chemical-amplification resist composition of the present invention preferably contains a basic compound, in addition to the above-described components.

The basic compound is preferably a nitrogen-containing organic basic compound.

The compound which can be used is not particularly limited but, for example, compounds classified into the following (1) to (4) are preferably used.

(1) Compound represented by the following formula (BS-1)

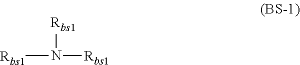

In formula (BS-1), each R_{bs1} independently represents any one of a hydrogen atom, an alkyl group (linear or branched), a cycloalkyl group (monocyclic or polycyclic), an aryl group and an aralkyl group. However, it does not occur that three R_{bs1}s all are a hydrogen atom.

The carbon number of the alkyl group as R_{bs1} is not particularly limited but is usually from 1 to 20, preferably from 1 to 12.

The carbon number of the cycloalkyl group as R_{bs1} is not particularly limited but is usually from 3 to 20, preferably from 5 to 15.

The carbon number of the aryl group as R_{bs1} is not particularly limited but is usually from 6 to 20, preferably from 6 to 10. Specific examples thereof include a phenyl group and a naphthyl group.

The carbon number of the aralkyl group as R_{bs1} is not particularly limited but is usually from 7 to 20, preferably from 7 to 11. Specific examples thereof include a benzyl group.

In the alkyl group, cycloalkyl group, aryl group or aralkyl group as R_{bs1}, a hydrogen atom may be substituted for by a substituent. Examples of the substituent include an alkyl group, a cycloalkyl group, an aryl group, an aralkyl group, a hydroxyl group, a carboxyl group, an alkoxy group, an aryloxy group, an alkylcarbonyloxy group, and an alkyloxycarbonyl group.

The compound represented by formula (BS-1) is preferably a compound where only one of three R_{bs1}s is a hydrogen atom or all R_{bs1}s are not a hydrogen atom.

Specific examples of the compound represented by formula (BS-1) include tri-n-butylamine, tri-n-pentyl amine, tri-n-octylamine, tri-n-decylamine, triisodecylamine, dicyclohexylmethyl amine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, and N,N-dihexylaniline.

Also, one preferred embodiment is a compound where in formula (BS-1), at least one R_{bs1} is an alkyl group substituted with a hydroxyl group. Specific examples of the compound include triethanolamine and N,N-dihydroxyethylaniline.

The alkyl group as R_{bs1} may have an oxygen atom in the alkyl chain to form an alkyleneoxy chain. The alkyleneoxy chain is preferably —CH₂CH₂O—. Specific examples thereof include tris(methoxyethoxyethyl)amine and compounds illustrated in column 3, line 60 et seq. of U.S. Pat. No. 6,040,112.

### (2) Compound Having a Nitrogen-Containing Heterocyclic Structure

The heterocyclic structure may or may not have aromaticity. Also, the heterocyclic structure may contain a plurality of nitrogen atoms and may further contain a heteroatom other than nitrogen. Specific examples of the compound include a compound having an imidazole structure (e.g., 2-phenylbenzimidazole, 2,4,5-triphenylimidazole), a compound having a piperidine structure (e.g., N-hydroxyethylpiperidine, bis(1,2,2,6,6-pentamethyl-4-piperidyl)sebacate), a compound having a pyridine structure (e.g., 4-dimethylaminopyridine), and a compound having an antipyrine structure (e.g., antipyrine, hydroxyantipyrine).

A compound having two or more ring structures is also suitably used. Specific examples thereof include 1,5-diazabicyclo[4.3.0]non-5-ene and 1,8-diazabicyclo[5.4.0]-undec-7-ene.

### (3) Amine Compound Having a Phenoxy Group

The amine compound having a phenoxy group has a phenoxy group at the terminal opposite the nitrogen atom of the alkyl group in an amine compound. The phenoxy group may have a substituent such as alkyl group, alkoxy group, halogen atom, cyano group, nitro group, carboxyl group, carboxylic acid ester group, sulfonic acid ester group, aryl group, aralkyl group, acyloxy group and aryloxy group.

A compound having at least one alkyleneoxy chain between the phenoxy group and the nitrogen atom is preferred. The number of alkyleneoxy chains per molecule is preferably from 3 to 9, more preferably from 4 to 6. Among alkyleneoxy chains, —CH₂CH₂O— is preferred.

Specific examples of the compound include 2-[2-{2-(2,2-dimethoxy-phenoxyethoxy)ethyl}-bis-(2-methoxyethyl)]-amine and Compounds (C1-1) to (C3-3) illustrated in paragraph [0066] of U.S. Patent Application Publication No. 2007/0224539A1.

### (4) Ammonium Salt

An ammonium salt is also appropriately used. The ammonium salt is preferably a hydroxide or a carboxylate. More specifically, a tetraalkylammonium hydroxide typified by tetrabutylammonium hydroxide is preferred. In addition, an ammonium salt derived from amines of (1) to (3) above can be also used.

Other examples of the basic compound which can be used include compounds synthesized in Examples of JP-A-2002-363146 and compounds described in paragraph 0108 of JP-A-2007-298569.

As for the basic compound, one basic compound is used alone, or two or more kinds of basic compounds are used in combination.

The amount of the basic compound used is usually from 0.001 to 10 mass %, preferably from 0.01 to 5 mass %, based on the solid content of the composition.

The molar ratio of acid generator/basic compound is preferably from 2.5 to 300. That is, the molar ratio is preferably 2.5 or more in view of sensitivity and resolution and is preferably 300 or less from the standpoint of suppressing reduction in the resolution due to thickening of the pattern with aging after exposure until heat treatment. This molar ratio is more preferably from 5.0 to 200, still more preferably from 7.0 to 150.

### [5] Resist Solvent

The solvent which can be used when preparing the composition is not particularly limited as long as it dissolves respective components, but examples thereof include an alkylene glycol monoalkyl ether carboxylate (e.g., propylene glycol monomethyl ether acetate (PGMEA; 1-methoxy-2-acetoxypropane)), an alkylene glycol monoalkyl ether (e.g., propylene glycol monomethyl ether (PGME; 1-methoxy-2-propanol)), an alkyl lactate (e.g., ethyl lactate, methyl lactate), a cyclic lactone (e.g., γ-butyrolactone; preferably having a carbon number of 4 to 10), a chain or cyclic ketone (e.g., 2-heptanone, cyclohexanone; preferably having a carbon number of 4 to 10), an alkylene carbonate (e.g., ethylene carbonate, propylene carbonate), and an alkyl carboxylate (preferably an alkyl acetate such as butyl acetate), an alkyl alkoxyacetate (e.g., ethyl ethoxypropionate). Other examples of the solvent which can be used include solvents described in paragraph [0244] et seq. of U.S. Patent Application Publication No. 2008/0248425A1.

Among the solvents above, an alkylene glycol monoalkyl ether carboxylate and an alkylene glycol monoalkyl ether are preferred.

One of these solvents may be used alone, or two or more thereof may be mixed and used. In the case of mixing two or more solvents, it is preferred to mix a solvent having a hydroxyl group and a solvent having no hydroxyl group. The mass ratio between the solvent having a hydroxyl group and the solvent having no hydroxyl group is from 1/99 to 99/1, preferably from 10/90 to 90/10, more preferably from 20/80 to 60/40.

The solvent having a hydroxy group is preferably an alkylene glycol monoalkyl ether, and the solvent having no hydroxyl group is preferably an alkylene glycol monoalkyl ether carboxylate.

The amount used of the solvent in the entire amount of the composition of the present invention may be appropriately adjusted according to the desired film thickness or the like but is generally adjusted to give a composition having an entire solid content concentration of 0.5 to 30 mass %, preferably from 0.7 to 20 mass %, more preferably from 1.0 to 10 mass %, still more preferably from 1.2 to 5 mass %.

### [6] Surfactant

The composition of the present invention preferably further contains a surfactant. The surfactant is preferably a fluorine-containing and/or silicon-containing surfactant.

Examples of the surfactant above include Megaface F176 and Megaface R08 produced by Dainippon Ink & Chemicals, Inc.; PF656 and PF6320 produced by OMNOVA; Troysol S-366 produced by Troy Chemical; Florad FC430 produced by Sumitomo 3M Inc.; and Polysiloxane Polymer KP-341 produced by Shin-Etsu Chemical Co., Ltd.

A surfactant other than the fluorine-containing and/or silicon-containing surfactant may be also used. Specific examples thereof include polyoxyethylene alkyl ethers and polyoxyethylene alkylaryl ethers.

In addition, known surfactants may be appropriately used. Examples of the surfactant which can be used include surfactants described in paragraph [0273] et seq. of U.S. Patent Application Publication No. 2008/0248425A1.

One kind of a surfactant may be used alone, or two or more kinds of surfactants may be used in combination.

The amount of the surfactant used is preferably from 0.0001 to 2 mass %, more preferably from 0.001 to 1 mass %, based on the entire solid content of the composition.

### [7] Other Additives

The composition of the present invention may appropriately contain, in addition to the components described above, a carboxylic acid, an onium carboxylate, a dissolution-inhibiting compound having a molecular weight of 3,000 or less described, for example, in Proceeding of SPIE, 2724, 355 (1996), a dye, a plasticizer, a photosensitizer, a light absorber, an antioxidant and the like.

In particular, a carboxylic acid is suitably used for enhancing the performance. The carboxylic acid is preferably an aromatic carboxylic acid such as benzoic acid and naphthoic acid.

The content of the carboxylic acid is preferably from 0.01 to 10 mass %, more preferably from 0.01 to 5 mass %, still more preferably from 0.01 to 3 mass %, based on the entire solid content concentration of the composition.

Also, in the case of using EUV light as the exposure light source, the composition may contain an additive capable of absorbing out-of-band light. Examples of the out-of-bad light absorber include aromatic compounds described in U.S. Patent Application Publication No. 2006/0223000.

### EXAMPLES

The present invention is described in greater detail below by referring to Examples, but the contents of the present invention are not limited thereto.

### [Compositions 1 to 7]

Each of compositions having the formulation shown in Table 1 was microfiltered through a membrane filter having a pore size of 0.1 μm to obtain a resist solution.

TABLE 1

| | | | | | | | | | Basic | | | | | | | | | |
|---|---|---|---|---|---|---|---|---|---|---|---|---|---|---|---|---|---|---|
| | Polymer Compound (A) | | | | Crosslinking Agent (B) | | Acid Generator (C) | | Compound | | Surfactant | | Resist Solvent | | | | | |
| Compo- | Polymer-1 | | | | XLinker-1 | | PAG-1 | | TBAH | | W-1 | | PGMEA | | PGME | | | |
| sition 1 | 0.7 | g | | | 0.2 | g | 0.08 | g | 0.02 | g | 0.005 | g | 60 | g | 15 | g | | |
| Compo- | Polymer-1 | | Polymer-2 | | XLinker-2 | | PAG-1 | | TBAH | | W-1 | | PGMEA | | PGME | | EL | |
| sition 2 | 0.3 | g | 0.32 | g | 0.2 | g | 0.1 | g | 0.03 | g | 0.005 | g | 30 | g | 30 | g | 15 | g |

| Compo- | Polymer-1 | | XLinker-1 | | XLinker-2 | | PAG-1 | | TBAH | | W-2 | | PGMEA | | PGME | | EL | |
|---|---|---|---|---|---|---|---|---|---|---|---|---|---|---|---|---|---|---|
| sition 3 | 0.635 | g | 0.1 | g | 0.1 | g | 0.12 | g | 0.045 | g | 0.005 | g | 30 | g | 30 | g | 15 | g |

| Compo- | Polymer-1 | | XLinker-3 | | PAG-1 | | PAG-3 | | TBAH | | W-1 | | PGMEA | | PGME | | EL | |
|---|---|---|---|---|---|---|---|---|---|---|---|---|---|---|---|---|---|---|
| sition 4 | 0.67 | g | 0.15 | g | 0.07 | g | 0.06 | g | 0.03 | g | 0.005 | g | 30 | g | 30 | g | 15 | g |

| Compo- | Polymer-1 | | XLinker-4 | | PAG-1 | | TBAH | | W-1 | | PGMEA | | PGME | |
|---|---|---|---|---|---|---|---|---|---|---|---|---|---|---|
| sition 5 | 0.78 | g | 0.1 | g | 0.1 | g | 0.02 | g | 0.005 | g | 60 | g | 15 | g |
| Compo- | Polymer-1 | | XLinker-5 | | PAG-2 | | TBAH | | W-1 | | PGMEA | | PGME | |
| sition 6 | 0.78 | g | 0.1 | g | 0.1 | g | 0.02 | g | 0.005 | g | 60 | g | 15 | g |
| Compo- | Polymer-2 | | XLinker-1 | | PAG-1 | | TBAH | | W-1 | | PGMEA | | PGME | |
| sition 7 | 0.68 | g | 0.2 | g | 0.1 | g | 0.02 | g | 0.005 | g | 60 | g | 15 | g |

Details of respective components denoted by abbreviations in Table 1 are given below.
<Polymer Compound> 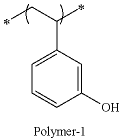
(Mass average molecular weight = 4000, polydispersity = 1.2) 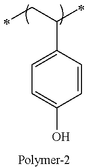
(Mass average molecular weight = 2800, polydispersity = 1.1) 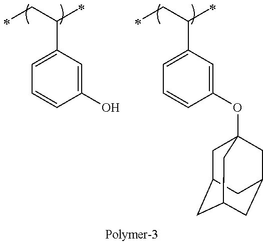
(Compositional ratio (by mol) = 95/5, mass average molecular weight = 3500, polydispersity = 1.1)
<Crosslinking Agent> 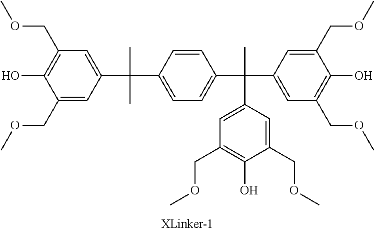 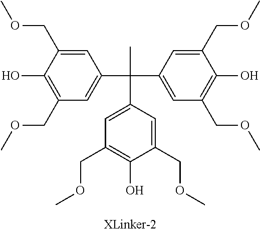 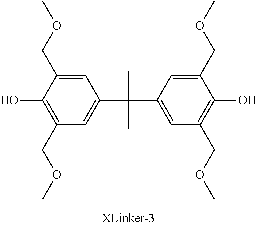 [SMILES: COCc1cc(C(C)(C)c2cc(COC)c(O)c(COC)c2)cc(COC)c1O] 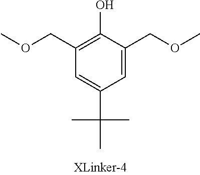 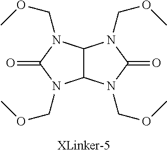
<Acid Generator> 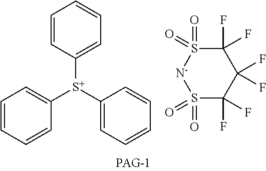 [SMILES: c1ccc([S+](c2ccccc2)c2ccccc2)cc1 ; O=S1(=O)[N-]S(=O)(=O)C(F)(F)C(F)(F)C1(F)F] 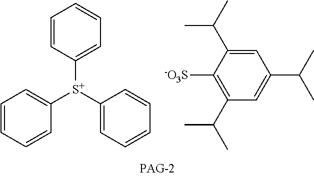 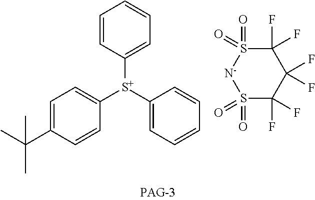 [SMILES: CC(C)(C)c1ccc([S+](c2ccccc2)c2ccccc2)cc1 ; O=S1(=O)[N-]S(=O)(=O)C(F)(F)C(F)(F)C1(F)F]
<Basic Compound>
TBAH: Tetrabutylammonium hydroxide
<Surfactant>
W-1: PF6320 (produced by OMNOVA)
W-2: Megaface F176 (produced by Dainippon Ink & Chemicals, Inc.)
<Resist Solvent>
PGMEA: Propylene glycol monomethyl ether acetate
PGME: Propylene glycol monomethyl ether
EL: Ethyl lactate

### EB Exposure Evaluation 1

### Examples 1 to 7 and Comparative Examples 1 to 8

Resist patterns were formed using the compositions shown in Table 1 by the following operation. Details of the conditions for resist pattern formation are shown in Table 2.

### [Coating of Resist]

A coating solution composition having the formulation shown in Table 2 was microfiltered through a membrane filter having a pore size of 0.1 μm to obtain a resist solution.

This resist solution was coated on a 6-inch Si wafer subjected to an HMDS (hexamethyldisilazane) treatment, by using a spin coater, Mark 8, manufactured by Tokyo Electron Ltd. and dried on a hot plate under the conditions shown in Table 2 to obtain a resist film having a thickness of 0.03 μm.

### [Exposure]

The thus-obtained resist film was exposed to a line pattern (length direction: 0.5 mm, number of lines drawn: 40) having a line width of 15 to 30 nm in steps of 2.5 nm by using an electron beam irradiation apparatus (JBX6000, manufactured by JEOL, accelerating voltage: 50 keV) and varying the exposure dose.

### [Post-Exposure Baking]

Immediately after the exposure, the resist film was heated on a hot plate under the conditions shown in Table 2.

### [Development]

Using a shower-type developing apparatus (ADE3000S, manufactured by ACTES), development was performed by ejecting and spraying the developer shown in Table 2 at a flow rate of 200 mL/min for the time shown in Table 2 while rotating the wafer at 50 revolutions (rpm).

Thereafter, a rinsing treatment was performed by ejecting and spraying the rinsing solution shown in Table 2 at a flow rate of 200 mL/min for the time shown in Table 2 while rotating the wafer at 50 revolutions (rpm).

Finally, the wafer was dried by high-speed spinning at 2,500 revolutions (rpm) for 60 seconds.

TABLE 2

| | | | | Development | | | |
|---|---|---|---|---|---|---|---|
| | | Baking Conditions | | | Developing | Rinsing | Rinsing |
| | Composition | After Coating | After Exposure | Developer | Time | Solution | Time |
| Example 1 | Composition 1 | 150° C. × 90 sec | 110° C. × 90 sec | 3-methylbutyl | 30 sec | decane | 10 sec |
| | | | | acetate | | | |
| Example 2 | Composition 2 | 150° C. × 90 sec | 110° C. × 90 sec | 3-methylbutyl | 30 sec | undecane | 10 sec |
| | | | | acetate | | | |
| Example 3 | Composition 3 | 150° C. × 90 sec | 110° C. × 90 sec | 3-methylbutyl | 30 sec | dodecane | 10 sec |
| | | | | acetate | | | |
| Example 4 | Composition 1 | 150° C. × 90 sec | 110° C. × 90 sec | n-hexyl acetate | 30 sec | undecane | 10 sec |
| Example 5 | Composition 1 | 150° C. × 90 sec | 110° C. × 90 sec | cyclohexyl | 60 sec | undecane | 10 sec |
| | | | | acetate | | | |
| Example 6 | Composition 2 | 150° C. × 90 sec | 110° C. × 90 sec | n-hexyl acetate | 30 sec | undecane | 10 sec |
| Example 7 | Composition 4 | 150° C. × 90 sec | 110° C. × 90 sec | n-butyl | 30 sec | undecane | 10 sec |
| | | | | n-butyrate | | | |
| Comparative | Composition 1 | 150° C. × 90 sec | 110° C. × 90 sec | n-butyl acetate | 30 sec | decane | 10 sec |
| Example 1 | | | | | | | |
| Comparative | Composition 1 | 150° C. × 90 sec | 110° C. × 90 sec | methyl amyl | 30 sec | decane | 10 sec |
| Example 2 | | | | ketone | | | |
| Comparative | Composition 1 | 150° C. × 90 sec | 110° C. × 90 sec | cycloheptanone | 30 sec | decane | 10 sec |
| Example 3 | | | | | | | |
| Comparative | Composition 1 | 150° C. × 90 sec | 110° C. × 90 sec | n-heptyl | 30 sec | decane | 10 sec |
| Example 4 | | | | acetate | | | |
| Comparative | Composition 5 | 150° C. × 90 sec | 110° C. × 90 sec | 3-methylbutyl | 30 sec | decane | 10 sec |
| Example 5 | | | | acetate | | | |
| Comparative | Composition 6 | 150° C. × 90 sec | 120° C. × 90 sec | cycloheptanone | 30 sec | decane | 10 sec |
| Example 6 | | | | | | | |
| Comparative | Composition 6 | 150° C. × 90 sec | 120° C. × 90 sec | 3-methylbutyl | 30 sec | decane | 10 sec |
| Example 7 | | | | acetate | | | |
| Comparative | Composition 7 | 150° C. × 90 sec | 110° C. × 90 sec | 3-methylbutyl | 30 sec | decane | 10 sec |
| Example 8 | | | | acetate | | | |

The resist pattern was evaluated for the following items. Details of the results are shown in Table 3.

### [Sensitivity]

The obtained pattern was observed using a scanning electron microscope (S-9220, manufactured by Hitachi, Ltd.). The electron beam irradiation dose when resolving a line width of 30 nm (line:space=1:1) was taken as the sensitivity.

### [Resolution]

The pattern having each line width was observed, and the minimum line width below which the line and space are not separately resolved was taken as the resolution.

### [Line Edge Roughness (LER)]

At arbitrary 30 points in the longitudinal 1 μm region of the line pattern with a line width of 30 nm, the distance from the reference line where the edge should be present was measured using a scanning electron microscope (S-9220, manufactured by Hitachi, Ltd.), and after determining the standard deviation, 36 was computed. A smaller value indicates better performance in terms of line edge roughness.

### [Scum in Unexposed Area]

The unexposed area adjacent to the line pattern with a line width of 30 nm was observed using a scanning electron microscope (S-9220, manufactured by Hitachi, Ltd.). The sample was rated A when no scum was observed in the unexposed area, rated B when slight scum was observed, and rated C when distinct scum was observed.

TABLE 3

| | | | | Scum in |
|---|---|---|---|---|
| | Sensitivity | Resolution | | Unexposed |
| | (μC/cm²) | (nm) | LER (nm) | Area |
| Example 1 | 90 | 17.5 | 5 | A |
| Example 2 | 90 | 17.5 | 4.8 | A |
| Example 3 | 90 | 17.5 | 4.7 | A |
| Example 4 | 85 | 17.5 | 4.5 | A |
| Example 5 | 85 | 17.5 | 4.5 | A |
| Example 6 | 90 | 17.5 | 4.5 | A |
| Example 7 | 85 | 17.5 | 5.5 | B |
| Comparative | 90 | 20 | 5 | A |
| Example 1 | | | | |
| Comparative | 90 | 22.5 | 8.5 | A |
| Example 2 | | | | |
| Comparative | 90 | 25 | 7.5 | A |
| Example 3 | | | | |
| Comparative | 80 | 25 | 7.5 | C |
| Example 4 | | | | |
| Comparative | 90 | 30 | 7 | A |
| Example 5 | | | | |
| Comparative | 90 | 30 | 8 | A |
| Example 6 | | | | |
| Comparative | unmeasurable | 30 nm, | unmeasurable | C |
| Example 7 | | unresolved | | |
| Comparative | 90 | 30 | 8 | A |
| Example 8 | | | | |

It is seen from the results in Table 3 that the composition according to the present invention can satisfy high sensitivity, high resolution, small line edge roughness (LER) and reduction of scum in the unexposed area all at the same time in the formation of an ultrafine (line width: 30 nm) pattern.

### EB Exposure Evaluation 2

### Examples 8 to 10

### [Coating of Resist]

The same composition as Composition 1 in Table 1 was coated on a Cr oxide film-deposited 6-inch wafer by using a spin coater, Mark 8, manufactured by Tokyo Electron Ltd. and dried on a hot plate under the conditions shown in Table 4 to obtain a resist film having a thickness of 0.03

### [Exposure]

The thus-obtained resist film was exposed by the same operation as in EB Exposure Evaluation 1 above.

### [Post-Exposure Baking]

Immediately after the irradiation, the resist film was heated on a hot plate under the conditions shown in Table 4.

### [Development]

Development was performed by the same operation as in EB Exposure Evaluation 1 above.

TABLE 4

| | | | | Development | | | |
|---|---|---|---|---|---|---|---|
| | | Baking Conditions | | | Developing | Rinsing | Rinsing |
| | Composition | After Coating | After Exposure | Developer | Time | Solution | Time |
| Example 8 | Composition 1 | 150° C. × 90 sec | 110° C. × 90 sec | 3-methylbutyl | 30 sec | dodecane | 10 sec |
| | | | | acetate | | | |
| Example 9 | Composition 1 | 150° C. × 90 sec | 110° C. × 90 sec | n-hexyl acetate | 30 sec | undecane | 10 sec |
| Example 10 | Composition 1 | 150° C. × 90 sec | 110° C. × 90 sec | cyclohexyl | 60 sec | undecane | 10 sec |
| | | | | acetate | | | |

Evaluations of sensitivity, resolution, line edge roughness (LER), and scum in the unexposed area were performed by the same methods as in EB Exposure Evaluation 1 above. Details of the results are shown in Table 5.

TABLE 5

| | Sensitivity | | LER | Scum in |
|---|---|---|---|---|
| | (μC/cm²) | Resolution (nm) | (nm) | Unexposed Area |
| Example 8 | 90 | 20 | 5 | A |
| Example 9 | 85 | 20 | 4.8 | A |
| Example 10 | 85 | 20 | 4.8 | A |

It is seen from the results in Table 5 that the composition according to the present invention can satisfy high sensitivity, high resolution, small line edge roughness (LER) and reduction of scum in the unexposed area all at the same time.

### EUV Exposure Evaluation

### Examples 11 to 13

### [Coating of Resist]

Composition 1 in Table 1 was coated on a 6-inch Si wafer subjected to an HMDS (hexamethyldisilazane) treatment, by using a spin coater, Mark 8, manufactured by Tokyo Electron Ltd. and dried on a hot plate under the conditions shown in Table 6 to obtain a resist film having a thickness of 40 nm.

### [Exposure]

The thus-obtained resist film was exposed to a 1:1 line-and-space pattern having a line width of 30 nm by using EUV light (wavelength: 13 nm).

### [Post-Exposure Baking]

Immediately after the exposure, the resist film was heated on a hot plate under the conditions shown in Table 6.

### [Development]

Development was performed by the same operation as in EB Exposure Evaluation 1 above.

TABLE 6

| | | | | Development | | | |
|---|---|---|---|---|---|---|---|
| | | Baking Conditions | | | Developing | Rinsing | Rinsing |
| | Composition | After Coating | After Exposure | Developer | Time | Solution | Time |
| Example 11 | Composition 1 | 150° C. × 90 sec | 110° C. × 90 sec | 3-methylbutyl | 30 sec | dodecane | 10 sec |
| | | | | acetate | | | |
| Example 12 | Composition 1 | 150° C. × 90 sec | 110° C. × 90 sec | n-hexyl acetate | 30 sec | undecane | 10 sec |
| Example 13 | Composition 1 | 150° C. × 90 sec | 110° C. × 90 sec | cyclohexyl | 60 sec | undecane | 10 sec |
| | | | | acetate | | | |

The resist pattern was evaluated for the following items. Details of the results are shown in Table 7.

### [Sensitivity]

The obtained pattern was observed using a scanning electron microscope (S-9220, manufactured by Hitachi, Ltd.). The EUV exposure dose when resolving a line width of 0.03 (30 nm) (line:space=1:1) was taken as the sensitivity.

### [Line Edge Roughness (LER)]

At arbitrary 30 points in the longitudinal 5 μm region of the line pattern with a line width of 0.03 μm (30 nm), the distance from the reference line where the edge should be present was measured using a scanning electron microscope (S-9220, manufactured by Hitachi, Ltd.), and after determining the standard deviation, 36 was computed. A smaller value indicates better performance in terms of line edge roughness.

### [Scum in Unexposed Area]

The unexposed area adjacent to the pattern with a line width of 0.03 μm (30 nm) was observed using a scanning electron microscope (S-9220, manufactured by Hitachi, Ltd.). The sample was rated A when no scum was observed in the unexposed area, rated B when slight scum was observed, and rated C when distinct scum was observed.

TABLE 7

| | Sensitivity (mJ/cm²) | LER (nm) | Scum in Unexposed Area |
|---|---|---|---|
| Example 11 | 25 | 5.5 | A |
| Example 12 | 25 | 5.4 | A |
| Example 13 | 25 | 5.3 | A |

It is seen from the results in Table 7 that the composition according to the present invention can satisfy high sensitivity, small line edge roughness (LER) and reduction of scum in the unexposed area all at the same time.

This application is based on Japanese patent application No. JP 2011-178533 filed on Aug. 17, 2011, the entire contents of which are hereby incorporated by reference, the same as if set forth at length.

What is claimed is:

1. A resist pattern forming method comprising, in order:
(1) a step of forming a resist film by using a negative chemical-amplification resist composition containing:
(A) polymer compound having a repeating unit represented by the following formula (I),
(B) a phenolic compound being capable of crosslinking the polymer compound (A) by the action of an acid and having two or more benzene rings and four or more alkoxymethyl groups, and
(C) a compound capable of generating an acid upon irradiation with an actinic ray or radiation,
(2) a step of exposing the film, and
(4) a step of, after exposure, developing the film by using a developer containing an ester-based solvent having a carbon number of 7 or 8: 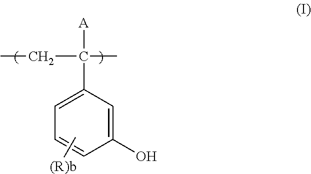
wherein, in formula (I), A represents a hydrogen atom, an alkyl group, a cycloalkyl group, a halogen atom or a cyano group;
R represents a halogen atom, an alkyl group, a cycloalkyl group, an aryl group, an alkenyl group, an aralkyl group, an alkoxy group, an alkylcarbonyloxy group or an alkylsulfonyloxy group, and when a plurality of Rs are present, each R may be the same as or different from every other R and they may combine to form a ring; and
b represents an integer of 0 to 2.

2. The resist pattern forming method according to claim 1,
wherein the ester-based solvent having a carbon number of 7 or 8 contained in the developer is an ester-based solvent represented by the following formula (II): 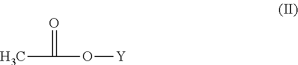
wherein, in formula (II), Y represents an alkyl group or a cycloalkyl group, having a carbon number of 5 or 6.

3. The resist pattern forming method according to claim 2,
wherein the ester-based solvent having a carbon number of 7 or 8 contained in the developer is one or more kinds of solvents selected from the group consisting of n-pentyl acetate, 3-methylbutyl acetate, 2-methylbutyl acetate, n-hexyl acetate, cyclohexyl acetate, 2-ethylbutyl acetate and 3-methylpentyl acetate.

4. The resist pattern forming method according to claim 1, further comprising:
(5) a step of performing a rinsing treatment by using an organic solvent containing one or more kinds of solvents selected from the group consisting of a monohydric alcohol-based solvent and a hydrocarbon-based solvent, after the development step (4).

5. The resist pattern forming method according to claim 1,
wherein in the development step (4), the development is performed by continuously supplying a developer.

6. The resist pattern forming method according to claim 1, further comprising:
(3) a baking step between the exposure step (2) and the development step (4).

7. The resist pattern forming method according to claim 1,
wherein the exposing in the exposure step (2) is performed by an electron beam or EUV light.

8. The resist pattern forming method according to claim 1,
wherein the negative chemical-amplification resist composition contains, as (C) the compound capable of generating an acid upon irradiation with an actinic ray or radiation, (C′) an ionic compound capable of generating an acid upon irradiation with an actinic ray or radiation in an amount of 9 mass % or more based on the entire solid content of the negative chemical-amplification resist composition.

9. The resist pattern forming method according to claim 1,
wherein the compound (C) is a compound capable of generating at least any acid of a sulfonic acid, a bis(alkylsulfonyl)imide and a tris(alkylsulfonyl)methide upon irradiation with an actinic ray or radiation.

10. A resist pattern formed by the resist pattern forming method according to claim 1.

11. A crosslinking negative chemical-amplification resist composition for organic solvent development, which is used for the resist pattern forming method according to claim 1.

12. A nanoimprint mold produced by the resist pattern forming method according to claim 1.

13. A photomask produced by the resist pattern forming method according to claim 1.
